(19) United States
(12) Patent Application Publication
(10) Pub. No.: US 2026/0123115 A1
(43) Pub. Date: Apr. 30, 2026

(54) LIGHT-EMITTING DEVICE WITH ALIGNED CENTRAL ELECTRODE AND OUTPUT APERTURE

(71) Applicant: LUMILEDS LLC, San Jose, CA (US)

(72) Inventor: Antonio LOPEZ-JULIA, Vaals (NL)

(73) Assignee: LUMILEDS LLC, San Jose, CA (US)

(21) Appl. No.: 19/003,923

(22) Filed: Dec. 27, 2024

Related U.S. Application Data
(63) Continuation of application No. PCT/US2023/026326, filed on Jun. 27, 2023.
(60) Provisional application No. 63/357,269, filed on Jun. 30, 2022.

(51) Int. Cl. H10H 20/851; H01L 25/075; H10H 20/80; H10H 20/82; H10H 20/857

(52) U.S. Cl. CPC H10H 20/8512; H10H 20/82; H10H 20/857; H10H 20/862; H10W 90/00

(57) ABSTRACT

A semiconductor LED includes p-doped, n-doped, and active layers, and has anode and cathode electrical contacts. The active layer extend to the side surfaces of the LED; the anode contact is on a central area of the p-doped layer and leaves peripheral regions without direct electrical coupling to the anode contact, reducing non-radiative recombination at the side surfaces. The LEDs include a front reflector with a central opening at least partly aligned with the anode contact. The LED can include front or back sets of nanostructured optical elements.

### PRIORITY CLAIM

This application is a continuation of App. No. PCT/US2023/026326 entitled “Light-emitting device with aligned central electrode and output aperture” filed 27 Jun. 2023 in the name of Antonio Lopez-Julia, which claims priority of U.S. provisional App. No. 63/357,269 entitled “Light-emitting device with aligned central electrode and output aperture” filed 30 Jun. 2022 in the name of Antonio Lopez-Julia, both of said applications being incorporated herein by reference in their entireties.

### FIELD OF THE INVENTION

The invention relates generally to light emitting diodes and to phosphor-converted light emitting diodes.

### BACKGROUND

Semiconductor light emitting diodes and laser diodes (collectively referred to herein as “LEDs”) are among the most efficient light sources currently available. The emission spectrum of an LED typically exhibits a single narrow peak at a wavelength determined by the structure of the device and by the composition of the semiconductor materials from which it is constructed. By suitable choice of device structure and material system, LEDs may be designed to operate at ultraviolet, visible, or infrared wavelengths.

LEDs may be combined with one or more wavelength converting materials (generally referred to herein as “phosphors”) that absorb light emitted by the LED and in response emit light of a longer wavelength. For such phosphor-converted LEDs (“pcLEDs”), the fraction of the light emitted by the LED that is absorbed by the phosphors depends on the amount of phosphor material in the optical path of the light emitted by the LED, for example on the concentration of phosphor material in a phosphor layer disposed on or around the LED and the thickness of the layer.

Phosphor-converted LEDs may be designed so that all of the light emitted by the LED is absorbed by one or more phosphors, in which case the emission from the pcLED is entirely from the phosphors. In such cases the phosphor may be selected, for example, to emit light in a narrow spectral region that is not efficiently generated directly by an LED.

Alternatively, pcLEDs may be designed so that only a portion of the light emitted by the LED is absorbed by the phosphors, in which case the emission from the pcLED is a mixture of light emitted by the LED and light emitted by the phosphors. By suitable choice of LED, phosphors, and phosphor composition, such a pcLED may be designed to emit, for example, white light having a desired color temperature and desired color-rendering properties.

Multiple LEDs or pcLEDs can be formed together on a single substrate to form an array. Such arrays can be employed to form active illuminated displays, such as those employed in, e.g., smartphones and smart watches, computer or video displays, signage, or visualization systems (such as augmented-or virtual-reality displays), or to form adaptive illumination sources, such as those employed in, e.g., automotive headlights, street lighting, camera flash sources, or flashlights (i.e., torches). An array having one or several or many individual devices per millimeter (e.g., device pitch or spacing of about a millimeter, a few hundred microns, or less than 100 microns, and separation between adjacent devices less than 100 microns or only a few tens of microns or less) typically is referred to as a miniLED array or a microLED array (alternatively, a μLED array). Such mini-or microLED arrays can in many instances also include phosphor converters as described above; such arrays can be referred to as pc-miniLED or pc-microLED arrays.

### SUMMARY

An inventive light-emitting element comprises a semiconductor light-emitting diode (LED), an anode electrical contact, a cathode electrical contact, a reflective or scattering layer, and front or back sets of nanostructured optical elements. The LED includes a p-doped semiconductor layer, an n-doped semiconductor layer, and an active, light-emitting layer between the p-doped and n-doped layers, and emits light at a nominal emission vacuum wavelength λ₀ resulting from radiative recombination of charge carriers at the active layer. The LED has (i) a light-exit surface of the n-doped layer opposite the active layer, (ii) an anode contact surface of the p-doped layer opposite the active layer, and (iii) side surfaces that laterally confine the entire p-doped layer, the entire active layer, and at least a portion of the n-doped layer. The active layer extends to the side surfaces. The cathode electrical contact is electrically coupled to the n-doped layer. The anode electrical contact is electrically coupled to the p-doped layer on a central area of the anode contact surface, leaving peripheral portions of the anode contact surface without direct electrical coupling to the anode electrical contact. The reflective or scattering layer is on peripheral portions of the light-exit surface and has a central opening therethrough. At least a portion of the central opening is positioned opposite at least a portion of the central area of the anode contact surface. The back set of multiple nanostructured optical elements (if present) can be positioned at the anode contact surface or on or within an electrically insulating back dielectric layer on the peripheral portions of the anode contact surface that lack direct electrical coupling to the anode electrical contact; the front set of multiple nanostructured optical elements (if present) can be positioned at the light-exit surface, on or within an electrically insulating front dielectric layer on the light-exit surface, or on or within the reflective or scattering layer.

In some instances, the anode contact can be electrically coupled to the p-doped layer on only the central area and of the anode contact surface and can be circumscribed by the peripheral portions of the anode contact surface that lack direct electrical coupling to the anode electrical contact. In some instances the light-emitting element can include reflective or scattering layers on at least portions of the anode contact surface or at least portions of the side surfaces. The reflective of scattering layers can form an optical cavity at least partly enclosing the n-and p-doped semiconductor layers and the active layer.

Objects and advantages pertaining to LEDs, pcLEDs, miniLED arrays, pc-miniLED arrays, microLED arrays, and pc-microLED arrays may become apparent upon referring to the examples illustrated in the drawings and disclosed in the following written description or appended claims.

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

### BRIEF DESCRIPTION OF THE DRAWINGS

FIG. 1 shows a schematic cross-sectional view of an example pcLED.

FIGS. 2A and 2B show, respectively, cross-sectional and top schematic views of an example array of pcLEDs.

FIG. 3A shows a schematic cross-sectional view of an example array of pcLEDs arranged with respect to waveguides and a projection lens. FIG. 3B shows an arrangement similar to that of FIG. 3A, but without the waveguides.

FIG. 4A shows a top schematic view of an example miniLED or microLED array and an enlarged section of 3×3 LEDs of the array. FIG. 4B is a side cross-sectional schematic diagram of an example of a close-packed array of multi-colored phosphor-converted LEDS on a monolithic die and substrate.

FIG. 5A is a schematic top view of a portion of an example LED display in which each display pixel is a red, green, or blue phosphor-converted LED pixel. FIG. 5B is a schematic top view of a portion of an example LED display in which each display pixel includes multiple phosphor-converted LED pixels (red, green, and blue) integrated onto a single die that is bonded to a control circuit backplane.

FIG. 6A shows a schematic top view an example electronics board on which an array of pcLEDs may be mounted, and FIG. 6B similarly shows an example array of pcLEDs mounted on the electronic board of FIG. 6A.

FIG. 7 is a schematic cross-sectional view of an example light-emitting element.

FIG. 8 is a schematic cross-sectional view of an example light-emitting element.

FIG. 9A is a schematic top view of a portion of an array of example light-emitting elements. FIG. 9B is a schematic cross-sectional view of two adjacent light-emitting elements of the array of FIG. 9A.

FIG. 10 is a schematic cross-sectional view of an example light-emitting element.

FIG. 11 is a schematic cross-sectional view of an example light-emitting element.

FIG. 12A is a schematic cross-sectional view of an example light-emitting element. FIG. 12B is a schematic cross-sectional view of an example light-emitting element.

FIG. 13 is a schematic cross-sectional view of an example light-emitting element.

FIG. 14 is a schematic cross-sectional view of an example light-emitting element.

FIG. 15 is a schematic cross-sectional view of an example light-emitting element.

FIG. 16 is a schematic cross-sectional view of an example light-emitting element.

FIG. 17 is a schematic cross-sectional view of an example light-emitting element.

FIG. 18 is a schematic cross-sectional view of an example light-emitting element.

FIG. 19 is a schematic cross-sectional view of an example light-emitting element.

FIG. 20 is a schematic cross-sectional view of a portion of an array of example light-emitting elements connected to a control circuit.

The examples depicted are shown only schematically; all features may not be shown in full detail or in proper proportion; for clarity certain features or structures may be exaggerated or diminished relative to others or omitted entirely; the drawings should not be regarded as being to scale unless explicitly indicated as being to scale. For example, individual LEDs may be exaggerated in their vertical dimensions or layer thicknesses relative to their lateral extent or relative to substrate or phosphor thicknesses. The examples shown should not be construed as limiting the scope of the present disclosure or appended claims.

### DETAILED DESCRIPTION

The following detailed description should be read with reference to the drawings, in which identical reference numbers refer to like elements throughout the different figures. The drawings, which are not necessarily to scale, depict selective examples and are not intended to limit the scope of the inventive subject matter. The detailed description illustrates by way of example, not by way of limitation, the principles of the inventive subject matter. For purposes of simplicity and clarity, detailed descriptions of well-known devices, circuits, and methods may be omitted so as not to obscure the description of the inventive subject matter with unnecessary detail.

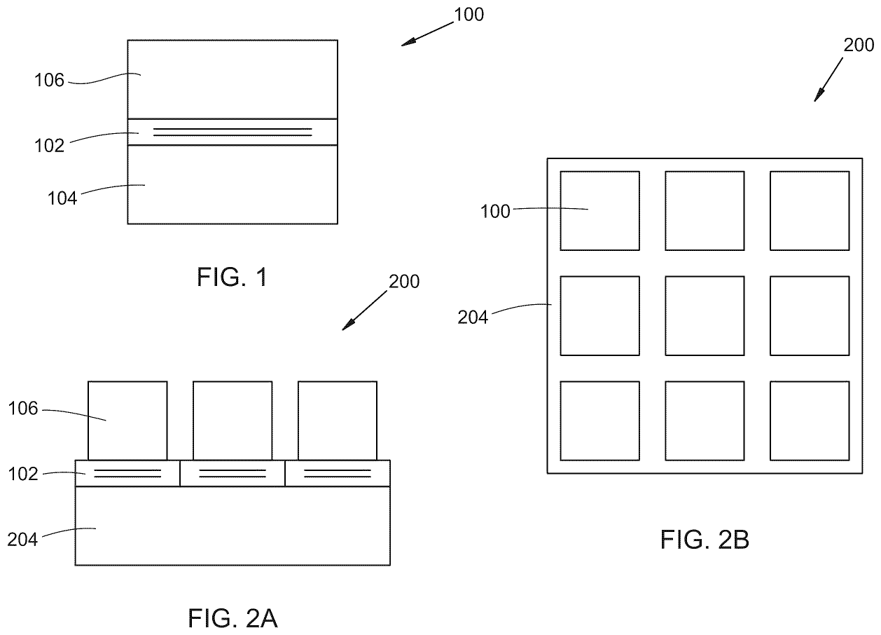

FIG. 1 shows an example of an individual pcLED 100 comprising a semiconductor diode structure 102 disposed on a substrate 104, together considered herein an “LED” or “semiconductor LED”, and a wavelength converting structure (e.g., phosphor layer) 106 disposed on the semiconductor LED. Semiconductor diode structure 102 typically comprises an active region disposed between n-type and p-type layers. Application of a suitable forward bias across the diode structure 102 results in emission of light from the active region. The wavelength of the emitted light is determined by the composition and structure of the active region.

The LED may be, for example, a III-Nitride LED that emits blue, violet, or ultraviolet light. LEDs formed from any other suitable material system and that emit any other suitable wavelength of light may also be used. Other suitable material systems may include, for example, III-Phosphide materials, III-Arsenide materials, other binary, ternary, or quaternary alloys of gallium, aluminum, indium, nitrogen, phosphorus, or arsenic, or II-VI materials.

Any suitable phosphor materials may be used for or incorporated into the wavelength converting structure 106, depending on the desired optical output from the pcLED.

FIGS. 2A and 2B show, respectively, cross-sectional and top views of an array 200 of pcLEDs 100, each including a phosphor pixel 106, disposed on a substrate 204. Such an array can include any suitable number of pcLEDs arranged in any suitable manner. In the illustrated example the array is depicted as formed monolithically on a shared substrate, but alternatively an array of pcLEDs can be formed from separate individual pcLEDs (e.g., singulated devices that are assembled onto an array substrate). Individual phosphor pixels 106 are shown in the illustrated example, but alternatively a contiguous layer of phosphor material can be disposed across multiple LEDs 102. In some instances the array 200 can include light barriers (e.g., reflective, scattering, and/or absorbing) between adjacent LEDs 102, phosphor pixels 106, or both. Substrate 204 may optionally include electrical traces or interconnects, or CMOS or other circuitry for driving the LED, and may be formed from any suitable materials.

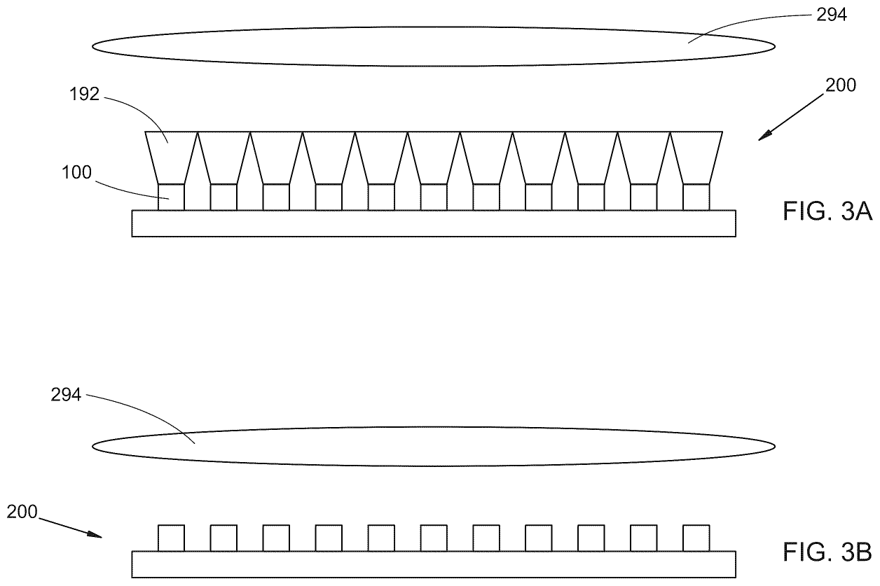

Individual pcLEDs 100 may optionally incorporate or be arranged in combination with a lens or other optical element located adjacent to or disposed on the phosphor layer. Such an optical element, not shown in the figures, may be referred to as a “primary optical element” and may be of any suitable type of arrangement (e.g., conventional refractive or diffractive optical elements, or so-called nanostructured optical elements such as those disclosed in, e.g., U.S. Pat. No. 11,327,283, U.S. Pub. No. 2020/0343416, U.S. Pub. No. 2020/0335661, U.S. Pub. No. 2021/0184081, U.S. Pub. No. 2022/0146079, or U.S. non-provisional application Ser. No. 17/825,143 filed May 26, 2022, each of which is incorporated by reference in its entirety). In addition, as shown in FIGS. 3A and 3B, a pcLED array 200 (for example, mounted on an electronics board) may be arranged in combination with secondary optical elements such as waveguides, lenses, or both for use in an intended application (for the entire array, for subsets thereof, or for individual pixels; of any suitable type or arrangement, e.g., conventional refractive or diffractive optical elements, or so-called nanostructured optical elements, including any of those listed above). In FIG. 3A, light emitted by each pcLED 100 of the array 200 is collected by a corresponding waveguide 192 and directed to a projection lens 294. Projection lens 294 may be a Fresnel lens, for example. This arrangement may be suitable for use, for example, in automobile headlights or other adaptive illumination sources. Other primary or secondary optical elements of any suitable type or arrangement can be included for each pixel, as needed or desired. In FIG. 3B, light emitted by pcLEDs of the array 200 is collected directly by projection lens 294 without use of intervening waveguides. This arrangement may particularly be suitable when pcLEDs can be spaced sufficiently close to each other, and may also be used in automobile headlights as well as in camera flash applications or other illumination sources. A miniLED or microLED display application may use similar optical arrangements to those depicted in FIGS. 3A and 3B, for example. Generally, any suitable arrangement of optical elements (primary, secondary, or both) can be used in combination with the pcLEDs described herein, depending on the desired application.

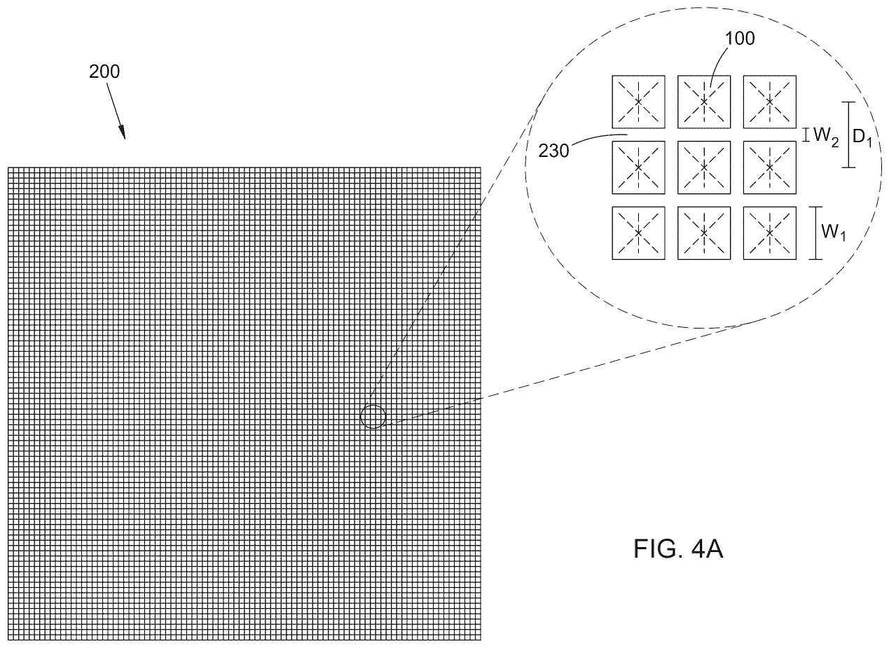

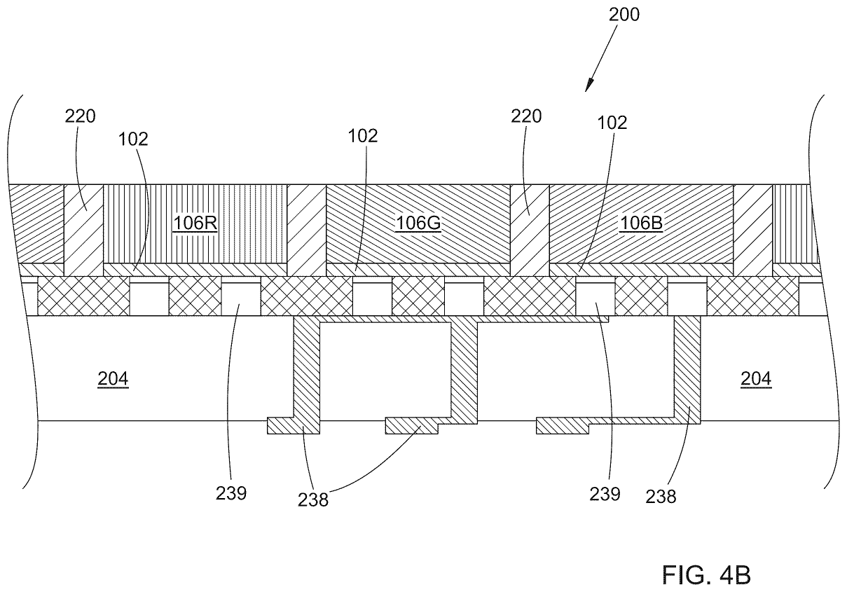

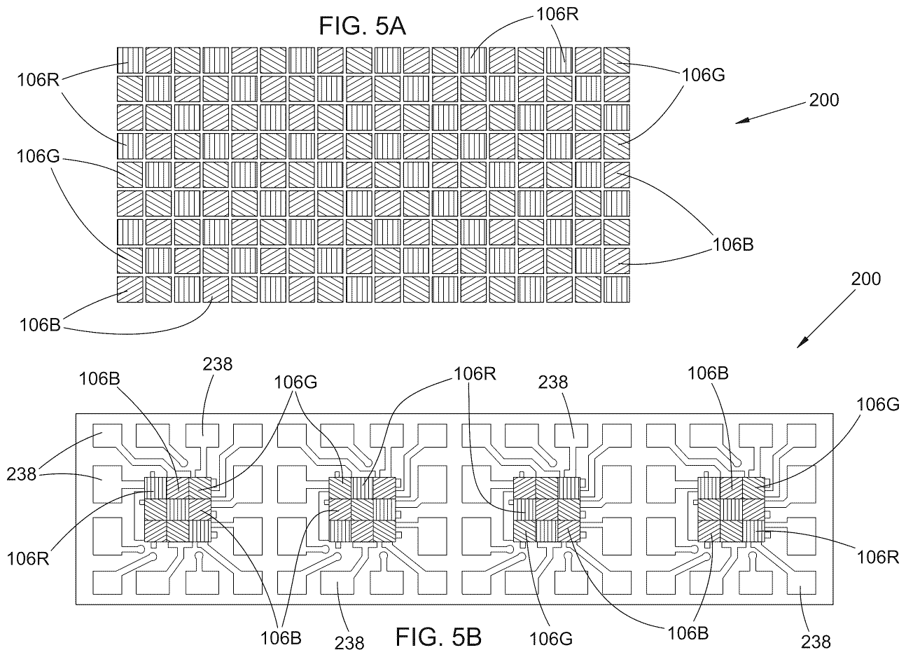

Although FIGS. 2A and 2B show a 3×3 array of nine pcLEDs, such arrays may include for example on the order of 10¹, 10², 10³, 10⁴, or more LEDs, e.g., as illustrated schematically in FIG. 4A. Individual LEDs 100 (i.e., pixels) may have widths w₁ (e.g., side lengths) in the plane of the array 200, for example, less than or equal to 1 millimeter (mm), less than or equal to 500 microns, less than or equal to 100 microns, or less than or equal to 50 microns. LEDs 100 in the array 200 may be spaced apart from each other by streets, lanes, or trenches 230 having a width w₂ in the plane of the array 200 of, for example, hundreds of microns, less than or equal to 100 microns, less than or equal to 50 microns, less than or equal to 20 microns, less than or equal to 10 microns, or less than or equal to 5 microns. The pixel pitch or spacing D₁ is the sum of w₁ and w₂. Although the illustrated examples show rectangular pixels arranged in a symmetric matrix, the pixels and the array may have any suitable shape or arrangement, whether symmetric or asymmetric. Multiple separate arrays of LEDs can be combined in any suitable arrangement in any applicable format to form a larger combined array or display.

LEDs having dimensions w₁ in the plane of the array (e.g., side lengths) of less than or equal to about 0.10 millimeters microns are typically referred to as microLEDs, and an array of such microLEDs may be referred to as a microLED array. LEDs having dimensions w₁ in the plane of the array (e.g., side lengths) of between about 0.10 millimeters and about 1.0 millimeters are typically referred to as miniLEDs, and an array of such miniLEDs may be referred to as a miniLED array.

An array of LEDs, miniLEDs, or microLEDs, or portions of such an array, may be formed as a segmented monolithic structure in which individual LED pixels are electrically isolated from each other, e.g., by trenches and/or insulating material. FIG. 4B is a schematic cross-sectional view of a close packed array 200 of multi-colored, phosphor converted LEDs 100 on a monolithic die and substrate 204. The side view shows GaN LEDs 102 attached to the substrate 204 through metal interconnects 239 (e.g., gold-gold interconnects or solder attached to copper micropillars) and metal interconnects 238. Phosphor pixels 106 are positioned on or over corresponding GaN LED pixels 102. The semiconductor LED pixels 102 or phosphor pixels 106 (often both) can be coated on their sides with a reflective mirror or diffusive scattering layer to form an optical isolation barrier 220 (which in some instances can also act as an electrical isolation barrier). In this example each phosphor pixel 106 is one of three different colors, e.g., red phosphor pixels 106R, green phosphor pixels 106G, and blue phosphor pixels 106B (still referred to generally or collectively as phosphor pixels 106). Such an arrangement can enable use of the LED array 200 as a color display.

The individual LEDs (pixels) in an LED array may be individually addressable, may be addressable as part of a group or subset of the pixels in the array, or may not be addressable. Thus, light emitting pixel arrays are useful for any application requiring or benefiting from fine-grained intensity, spatial, and temporal control of light distribution. These applications may include, but are not limited to, precise special patterning of emitted light from pixel blocks or individual pixels, in some instances including the formation of images as a display device. Depending on the application, emitted light may be spectrally distinct, adaptive over time, and/or environmentally responsive. The light emitting pixel arrays may provide preprogrammed light distribution in various intensity, spatial, or temporal patterns. The emitted light may be based at least in part on received sensor data and may be used for optical wireless communications. Associated electronics and optics may be distinct at a pixel, pixel block, or device level.

FIGS. 5A and 5B are examples of LED arrays 200 employed in display applications or visualization systems (e.g., augmented-or virtual-reality systems), wherein an LED display includes a multitude of display pixels. In some examples (e.g., as in FIG. 5A), each display pixel comprises a single semiconductor LED pixel 102 and a corresponding phosphor pixel 106R, 106G, or 106B of a single color (red, green, or blue). Each display pixel only provides one of the three colors. In some examples (e.g., as in FIG. 5B), each display pixel includes multiple semiconductor LED pixels 102 and multiple corresponding phosphor pixels 106 of multiple colors. In the example shown each display pixel includes a 3×3 array of semiconductor pixels 102; three of those LED pixels have red phosphor pixels 106R, three have green phosphor pixels 106G, and three have blue phosphor pixels 106B. Each display pixel can therefore produce any desired color combination. In the example shown the spatial arrangement of the different colored phosphor pixels 106 differs among the display pixels; in some examples (not shown) each display pixel can have the same arrangement of the different colored phosphor pixels 106.

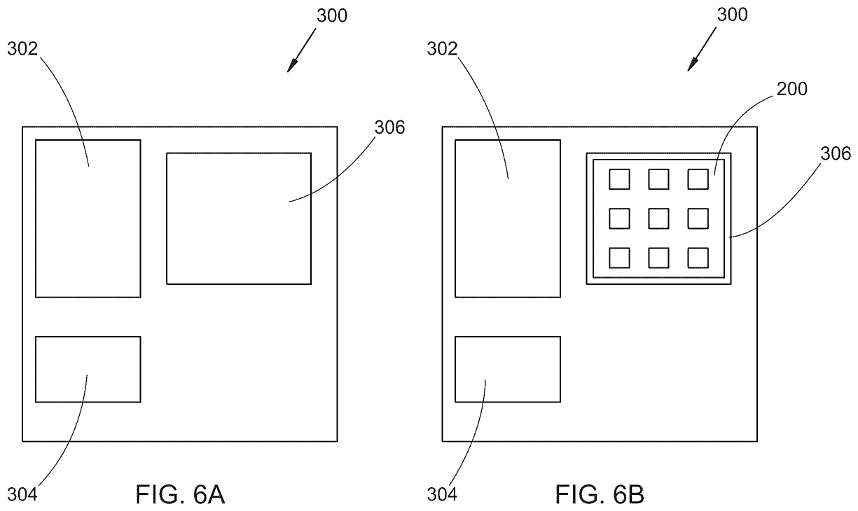

As shown in FIGS. 6A and 6B, a pcLED array 200 may be mounted on an electronics board 300 comprising a power and control module 302, a sensor module 304, and an LED attach region 306. Power and control module 302 may receive power and control signals from external sources and signals from sensor module 304, based on which power and control module 302 controls operation of the LEDs. Sensor module 304 may receive signals from any suitable sensors, for example from temperature or light sensors. Alternatively, pcLED array 200 may be mounted on a separate board (not shown) from the power and control module and the sensor module.

For purposes of the present disclosure and appended claims, “forward”, “backward”, upward”, “downward”, or “vertical” directions are generally perpendicular to the layers of the diode structure 102 and wavelength-converting layer 106 (if present); “lateral” or “horizontal” directions are generally parallel to those layers. Designations of directions or surfaces as, e.g., “front”, “forward”, “top”, or “upper” versus “back”, “backward”, “rear”, “rearward”, “bottom”, or “lower” are generally arbitrary but employed consistently only for convenience of description. For purposes of the present disclosure and appended claims, any arrangement of a layer, surface, substrate, diode structure, or other structure “on,” “over,” or “against” another such structure shall encompass arrangements with direct contact between the two structures as well as arrangements including some intervening structure between them. Conversely, any arrangement of a layer, surface, substrate, diode structure, or other structure “directly on,” “directly over,” or “directly against” another such structure shall encompass only arrangements with direct contact between the two structures. For purposes of the present disclosure and appended claims, a layer, structure, or material described as “transparent” or “substantially transparent” shall exhibit, at the nominal emission vacuum wavelength λ₀, a level of optical transmission that is sufficiently high, or a level of optical loss (due to absorption, scattering, or other loss mechanism) that is sufficiently low, that the light-emitting device can function within operationally acceptable parameters (e.g., output power or luminance, conversion or extraction efficiency, or other figures-of-merit including those described below).

A semiconductor LED produces light when charge carriers recombine in the active layer and emit photons. Competing with that desirable, radiative carrier recombination process are various undesirable, non-radiative carrier recombination processes. Carriers that recombine non-radiatively do not produce light, and so reduce the overall current-to-light conversion efficiency of the LED. Non-radiative recombination is more likely to occur at crystalline defect sites or surface states in the semiconductor materials of the LED, and are particularly likely to occur at the side surfaces of the device where the semiconductor material has been etched or cut or otherwise altered (and so having a relatively high density of defect sites or surface states). As the size of an LED decreases (e.g., as smaller individual LEDs are used to create miniLED or microLED arrays), the ratio of device perimeter to device area increases, increasing the fraction of carriers that combine non-radiatively. It would be desirable to provide a light-emitting element arranged so as to at least reduce the likelihood of non-radiative recombination at side surfaces of the light-emitting element.

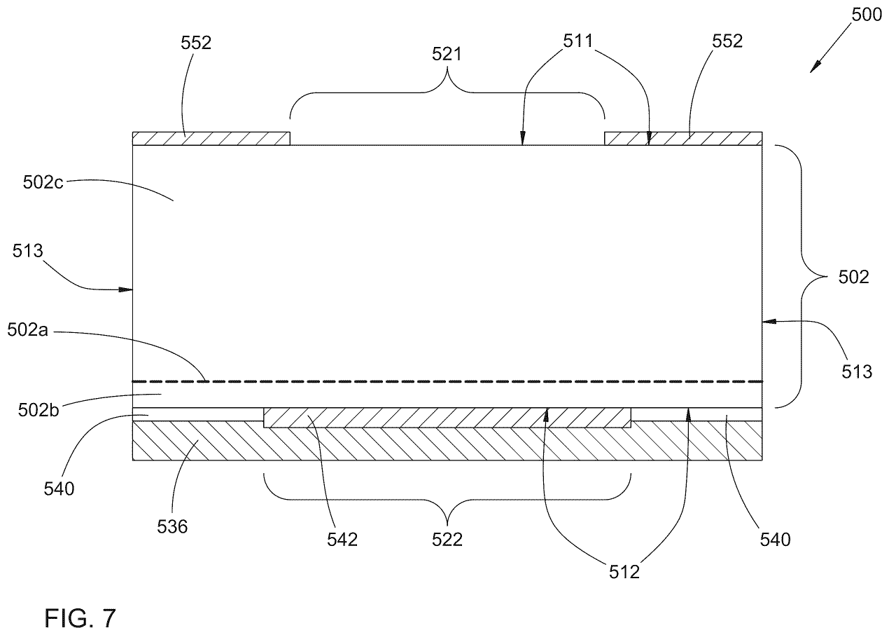

An inventive light-emitting element 500 (e.g., as in the examples illustrated schematically in FIGS. 7 through 19) includes a semiconductor light-emitting diode (LED) 502 and anode and cathode electrical contacts. The semiconductor LED 502 includes a p-doped semiconductor layer 502b, an n-doped semiconductor layer 502c, and an active, light-emitting layer 502a between the p-doped and n-doped layers 502b/502c. The LED has (i) a light-exit surface 511 of the n-doped layer 502c opposite the active layer 502a, (ii) an anode contact surface 512 of the p-doped layer 502b opposite the active layer 502a, and (iii) one or more side surfaces 513 that laterally confine the p-doped layer 502b, the active layer 502a, and at least a portion of the n-doped layer 502c. The active layer 502a extends to the side surfaces 513. In some examples the side surface(s) 513 laterally confine the entire n-doped layer 502c.

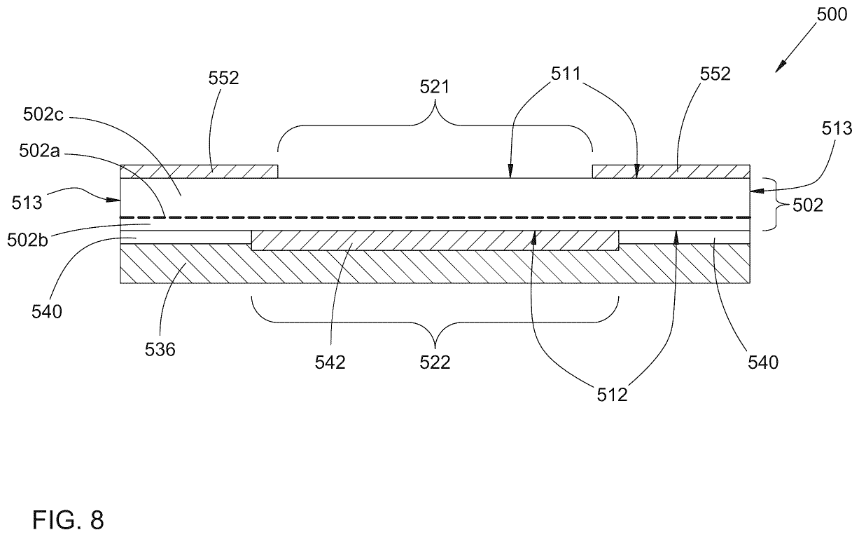

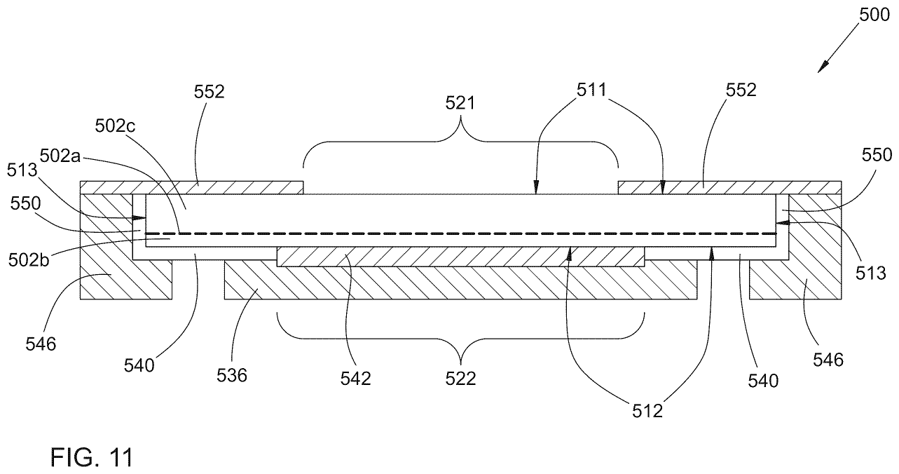

In some examples, the LED, including any one or more of its constituent layers 502a/502b/502c, can include one or more doped or undoped III-V, II-VI, or Group IV semiconductor materials or alloys or mixtures thereof. In some examples, the active layer 502a can include one or more p-n junctions, one or more quantum wells, one or more multi-quantum wells, or one or more quantum dots. In some examples the nominal emission vacuum wavelength λ₀ can be greater than 0.20 μm, greater than 0.4 μm, greater than 0.8 μm, less than 10. μm, less than 2.5 μm, or less than 1.0 μm. In some examples (e.g., the examples of FIG. 8 or 11) the total nonzero thickness of the layers 502a/502b/502c of the LED can be less than 20 μm, less than 10. μm, less than 5 μm, less than 3 μm, less than 2 μm, less than 1.5 μm, or less than 1.0 μm. In some examples the nonzero thickness of the p-doped layer can be less than 2 μm, less than 1.0 μm, less than 0.8 μm, less than 0.5 μm, less than 0.3 μm, less than 0.2 μm, or less than 0.10 μm. In some examples the layers of the LED support at most 15, 10, 8, 5, or 3 laterally propagating optical modes (for purposes of this disclosure, those propagating optical modes supported by the semiconductor layer structure of the LED that have qualitatively similar vertical intensity profiles (e.g., same numbers of peaks and nodes), regardless of lateral propagation direction or lateral intensity profile, shall be referred to collectively as only one mode among the supported optical modes. In some examples nonzero thickness of the p-doped layer can be selected so as to result in an angular distribution of emitted light within the LED that approximates a specified angular distribution; see, e.g., U.S. non-provisional application Ser. No. 17/701,319 filed Mar. 22, 2022 or U.S. provisional App. Nos. 63/232,960 filed Aug. 13, 2021, 63/232,965 filed Aug. 13, 2021, or 63/233,043 filed Aug. 13, 2021, each of which is incorporated by reference in its entirety).

The anode electrical contact is positioned on the anode contact surface 512 and is electrically coupled to the p-doped layer 502b; the cathode electrical contact is electrically coupled to the n-doped layer 502c. The anode electrical contact is electrically coupled to the p-doped layer 502b on a central area 522 of the anode contact surface 512, leaving peripheral portions of the anode contact surface 512 without direct electrical coupling to the anode electrical contact. In some examples the central area 522 of the anode contact surface 512 is circumscribed (i.e., entirely surrounded on the anode contact surface 512) by peripheral portions of the anode contact surface 512 that lack direct electrical coupling to the anode electrical contact. In such an arrangement, no current, or only negligible current, flows to/from peripheral regions of the active layer 502a through the p-doped layer 502b. Current flows between the anode electrical contact and the active layer 502a (through the p-doped layer 502b) in their respective central areas, avoiding the side surfaces 513 and its defect sites or surface states that could mediate non-radiative carrier recombination. Lateral diffusion of charge carriers within the active layer 502a can result in some light emission from peripheral regions of the active layer 502a.

In some instances a suitably large distance between the side surfaces 513 and the perimeter of the central area 522 of the anode contact surface 512 can be selected based on typical carrier radiative lifetimes and on typical carrier lateral diffusion rates. A distance can be selected so that a majority of carriers will have radiatively recombined within the time required for a majority of those carriers to have diffused across the selected distance. In some examples radiative recombination may be likely to occur by the time the carriers have diffused over distances of about 1 to 5 μm. In some examples a suitably large distance can be selected empirically. A series of test devices can be fabricated with different distances between the side surfaces 513 and the perimeter of the central area 522 of the anode contact surface 512. Overall current-to-light conversion efficiency can be measured, and might be expected to go through a maximum at some non-zero distance or over a range of distances between the side surfaces 513 and the central area of the anode contact surface 512. From its value when the anode electrical contact extends all the way to the side surfaces 513, the conversion efficiency would be expected to increase with increasing separation, and then eventually decrease as the separation becomes so large that peripheral regions of the active layer 502a begin to emit less or no light. In some examples, separation between lateral edges of the central area 522 of the anode contact surface 512 and the side surfaces 513 can be greater than 1.0 μm, 2 μm, 5 μm, 10. μm, 20 μm, or 50 μm.

In some examples the light-emitting element 500 includes a reflective or scattering layer on peripheral portions of the light-exit surface 511 so that there is a central opening 521 through the reflective or scattering layer. In some examples, separation between lateral edges of the central opening and the side surfaces can be greater than 1.0 μm, 2 μm, 5 μm, 10. μm, 20 μm, or 50 μm. Most or all of the light exiting through the light-exit surface 511 passes through the central opening 521. At least a portion of the central opening 521 is positioned opposite at least a portion of the central area 522 of the anode contact surface 512, i.e., an outline of the central opening 521 projected downward onto the anode contact surface 512 at least partly overlaps the central area 522. Such an arrangement can be usefully employed, e.g., in examples having the cathode electrical contact blocking light transmission through a peripheral portion of the light-exit surface 511, and can enhance the fraction of light emitted by the active layer 502a, resulting from current flow through the anode electrical contact on the central area 522, that escapes through the light-exit surface 511. In some examples the entire central opening 521 can be positioned opposite at least a portion of the central area 522 of the anode contact surface 512; in some examples the entire central area 522 of the anode contact surface 512 can be positioned opposite at least a portion of the central opening 521. In some examples the central opening 521 can be concentrically positioned opposite the central area of the anode contact surface (e.g., their respective centroids can be aligned along a vertical line); in some of those examples the central opening 521 and the central area 522 of the anode contact surface 512 can be substantially the same size and shape.

In some examples, the light-emitting element 500 includes reflective or scattering layers on peripheral portions of the light-exit surface 511, at least portions of the anode contact surface 512, or at least portions of the side surfaces 513; some examples can include all of those. The reflective or scattering layer on the light-exit surface 511 has a central opening 521, arranged in any of the ways described above. The reflective or scattering layers on the surfaces 511, 512, and 513 can form an optical cavity at least partly enclosing the n-doped, p-doped, and active layers 502c/502b/502a. In some examples the optical cavity can be arranged so that emitted light exits the element 500 only through the central opening 521. In some examples the optical cavity can be arranged as a resonant cavity supporting one or more resonant optical modes. The element 500 can be arranged so that nodes or antinodes of one or more resonant optical modes are suitably placed for, e.g., increasing the Purcell factor for emission by the active layer 502a, enhancing the directionality of emission by the active layer 502a or transmission through the light-exit surface 511, or decreasing optical loss at the side surfaces 513 or the anode contact surface 512.

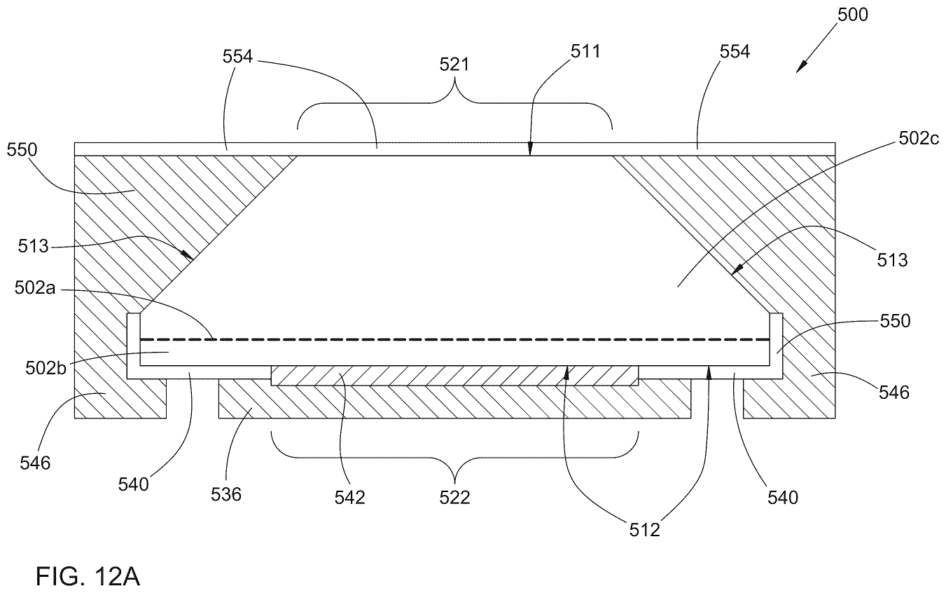

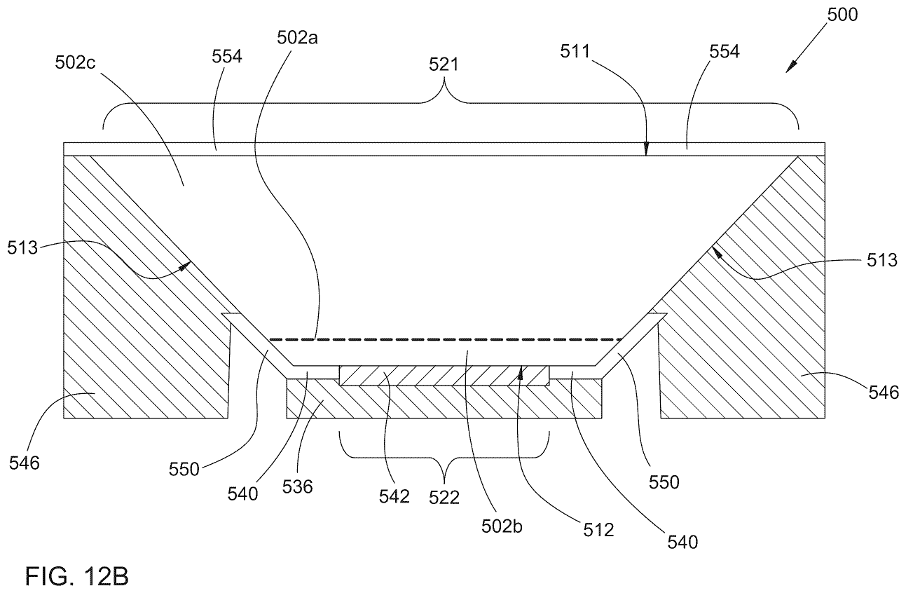

In some examples the light-emitting element 500 includes side surfaces 513 that are substantially flat and substantially perpendicular to the light-exit surface 511 and the anode contact surface 512. In some of those examples the side surfaces 513 can be flat in two dimensions, e.g., as side facets of a square or rectangular element 500; in some of those examples the side surfaces 513 can be flat in only the vertical dimension, e.g., as the side surface of a cylindrical element 500. In some examples the side surfaces 513 can form obtuse internal angles with the light-exit surface 511 (e.g., as in FIG. 12A); in some examples the side surfaces 513 can form obtuse internal angles with the anode contact surface 512 (e.g., as in FIG. 12B, or in various examples disclosed in U.S. provisional App. No. 63/289,607 filed Dec. 14, 2021, which is incorporated by reference in its entirety). In the example of FIG. 12A, the side surfaces 513 can “funnel” emitted light toward the central opening 521. In the example of FIG. 12B, the side surfaces 513 can collect laterally propagating light and redirect it toward the light-exit surface 511.

In some examples the light-emitting element 500 can include an electrically insulating back dielectric layer 540 on the peripheral portions of the anode contact surface 512 that lack direct electrical coupling to the anode electrical contact. The back dielectric layer 540 can include one or more materials among: doped or undoped silicon oxide, nitride, or oxynitride; one or more doped or undoped semiconductor oxides, nitrides, or oxynitrides; one or more doped or undoped metal oxides, nitrides, or oxynitrides; one or more optical glasses; or one or more doped or undoped polymers. In some examples the back dielectric layer 540 can include only a single layer of a single dielectric material; in other examples the back dielectric layer 540 can include multiple layers or multiple materials.

In some examples (e.g., as in any of FIG. 7-12B or 16) the anode electrical contact can include a metal layer 542 in direct contact with the central area 522 of the anode contact surface 512. The metal layer 542 can include one or more of aluminum, silver, gold, or other metal or metallic alloy. The metal layer 542 can be electrically coupled to an anode bonding layer 536 that in turn can be electrically coupled, e.g., to electrical traces or other circuitry arranged for conveying electrical current to/from the p-doped layer 502b of the light-emitting element 500 through the central area 522 of the anode contact surface 512. The anode bonding layer 536 is electrically isolated from the active and n-doped layers 502a/502c, meaning there is no direct electrical coupling between the anode boding layer 536 and the active and n-doped layers 502a/502c; however, there is indirect electrical coupling through the p-doped layer 502b. In some examples (not shown) the anode electrical contact can be a portion of an electrically conductive anode bonding layer 536 that is in direct electrical contact with the central area 522 of the anode contact surface 512. The anode bonding layer 536 can include one or more of aluminum, silver, gold, or other metal or metallic alloy.

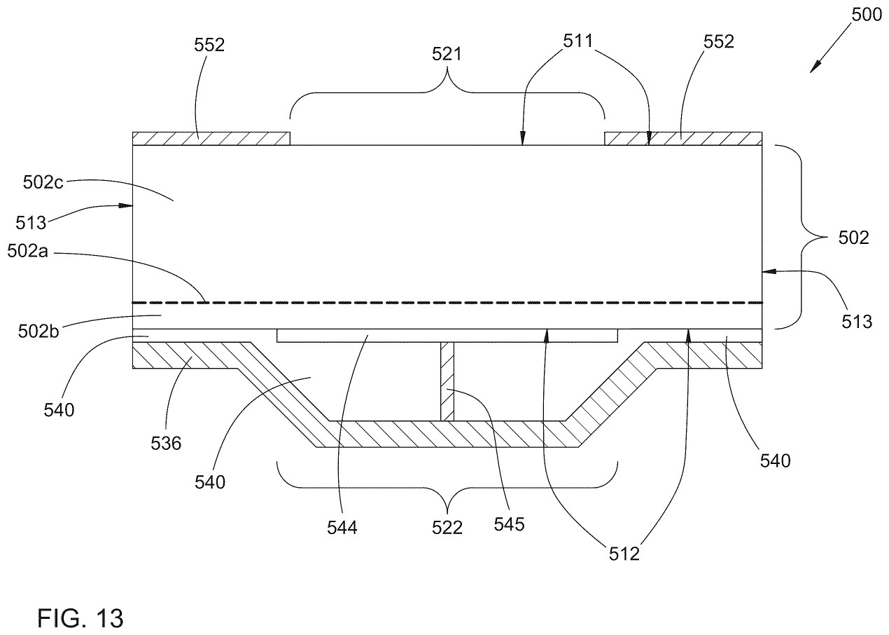

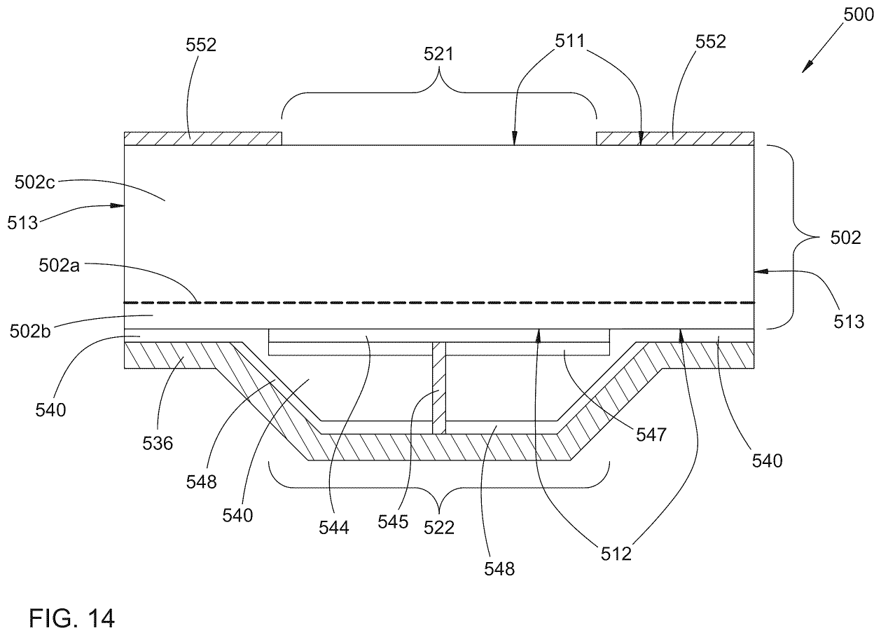

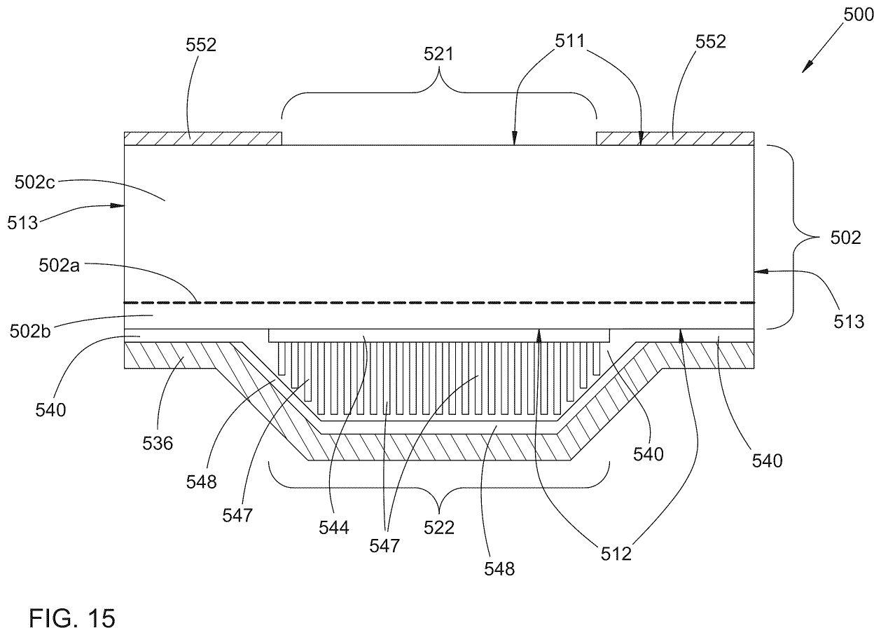

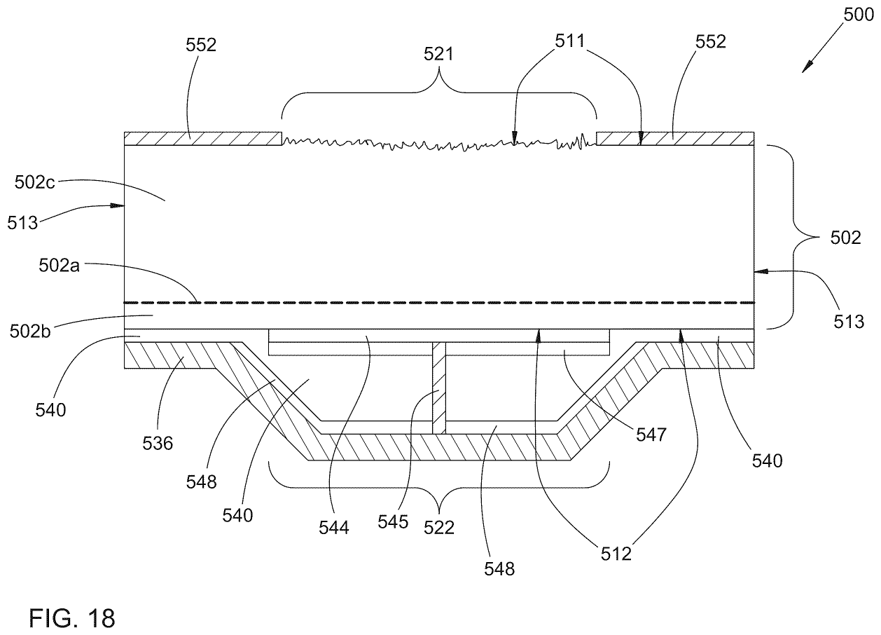

In some examples (e.g., as in any of FIG. 13-15 or 17-19) the anode electrical contact can include a transparent conductive oxide (TCO) layer 544 in direct contact with the central area 522 of the anode contact surface 512. The TCO layer can include one or more of indium tin oxide, indium zinc oxide, one or more other transparent conductive oxides, or combinations or mixtures thereof. In such examples the back dielectric layer 540 can cover the TCO layer 544 opposite the anode contact surface 512 (e.g., as in any of FIG. 13-15 or 17-19). In such examples the light-emitting element 500 can include at least one circumscribed, localized, electrically conductive via 545 electrically coupled to the TCO layer 544 and passing through the back dielectric layer 540 (not shown in FIG. 18 to reduce clutter for better clarity). In some examples the via 545 electrically couples the TCO layer 544 to the anode bonding layer 536. In some examples (e.g., as in any of FIGS. 14, 15, or 17-19) the light-emitting element 500 can include a back reflector 548 on the back dielectric layer 540 opposite the TCO layer 544 and the anode contact surface 512. In some examples the back reflector 548 can include one or more of a metal layer, a dielectric multilayer reflector, or a distributed Bragg reflector, and can include one or more materials among: one or more metals or metal alloys; doped or undoped silicon; one or more doped or undoped III-V, II-VI, or Group IV semiconductors; doped or undoped silicon oxide, nitride, or oxynitride; one or more doped or undoped semiconductor oxides, nitrides, or oxynitrides; one or more doped or undoped metal oxides, nitrides, or oxynitrides; one or more optical glasses; or one or more doped or undoped polymers. If the back reflector 548 is electrically conductive, it can be electrically coupled to the via 545 and to the anode bonding layer 536; in some examples the anode boding layer 536 can act as the back reflector 548. If the back reflector 548 is electrically non-conductive, then the via 545 can pass through it.

In some examples (e.g., as in any of FIGS. 13-15, 18, and 19) the back dielectric layer 540 can include a central portion, opposite at least the central area 522 of the anode contact surface 512, that protrudes away from the anode contact surface 512. The protruding portion of the back dielectric layer 540 can be arranged so as to redirect a portion of light propagating from the active layer 502a through the anode contact surface 512 to propagate back through the anode contact surface 512 toward the light-exit surface 511. The protruding portion of the back dielectric layer 540 thus can act as a light collector for the light-emitting element 500. In some examples the protruding central portion of the back dielectric layer 540 can have a tapered shape that decreases in transverse extent with increasing distance from the anode contact surface 512. Examples of such structures are disclosed in, e.g., U.S. provisional App. No. 63/289,607 incorporated above.

In some examples (e.g., as in any of FIGS. 14, 15, 18, or 19) the light-emitting element 500 can include a back set of multiple nanostructured optical elements 547 characterized by at least one element size relative to the nominal emission vacuum wavelength λ₀ and by at least one element shape (e.g., cylindrical, frusto-conical, frusto-pyramidal, and so forth). The nanostructured optical elements 547 can be positioned on or within the back dielectric layer 540 or at the anode contact surface 512, and can be arranged as an array of elements characterized by at least one element spacing relative to the nominal emission vacuum wavelength λ₀. The element size, shape, and spacing of the back set can be selected to result in one or more of (1) non-specular reflective redirection of at least a portion of light at the nominal emission vacuum wavelength λ₀ propagating within the dielectric layer to propagate toward the light-exit surface, (2) non-specular reflective or non-refractive transmissive redirection of at least a portion of light at the nominal emission vacuum wavelength λ₀ incident on the anode contact surface to propagate toward the light-exit surface, (3) increased Purcell factor for emission of light by the active layer, or (4) enhanced directionality of light emitted by the active layer. Examples of such nanostructured layers are disclosed in the various references incorporated above in the discussion of primary and secondary optical elements for the pcLEDs 100 of the array 200.

In some examples the nanostructured elements 547 of the back set can include a multitude of suitably sized and shaped projections, holes, depressions, inclusions, or structures. In some examples the nanostructured elements 547 of the back set can include an array of single or double nano-antennae or an array of meta-atoms or meta-molecules (e.g., as illustrated schematically in the examples of FIGS. 14, 18, and 19), a partial photonic bandgap structure, or a photonic crystal (e.g., as illustrated schematically in the examples of FIG. 15). In some examples nonzero size or spacing of the nanostructured elements 547 of the back set, or nonzero spacing between the active layer 502a and the nanostructured elements 547 of the back set, can be less than λ₀/n_{P}, less than λ₀/2n_{P}, less than λ₀/4n_{P}, or less than λ₀/10n_{P}, where n_{P} is the refractive index of the p-doped layer. In some examples nonzero size or spacing of the nanostructured elements 547 of the back set can be less than λ₀/n_{B}, less than λ₀/2n_{B}, less than λ₀/4n_{B}, or less than λ₀/10n_{B}, where n_{B} is the refractive index of the back dielectric layer. In some examples the nanostructured elements 547 of the back set can include one or more materials among: one or more metals or metal alloys; doped or undoped silicon; one or more doped or undoped III-V, II-VI, or Group IV semiconductors; doped or undoped silicon oxide, nitride, or oxynitride; one or more doped or undoped metal oxides, nitrides, or oxynitrides; one or more doped or undoped semiconductor oxides, nitrides, or oxynitrides; one or more optical glasses; or one or more doped or undoped polymers.

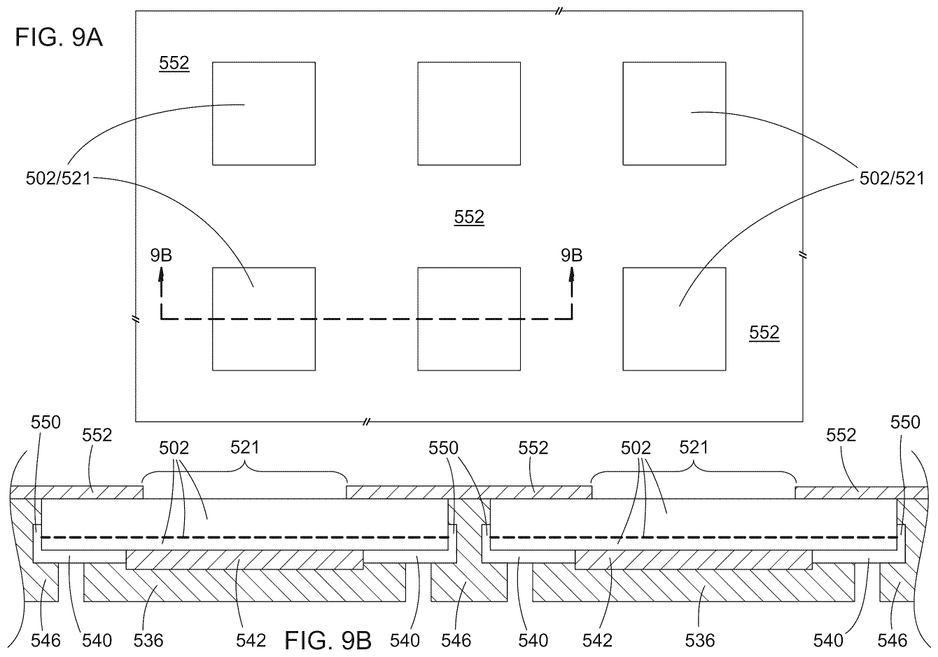

In some examples (e.g., as in any of FIGS. 9B, 10, 11, 12A/12B, 16, 17, or 19), the light-emitting element 500 can include an electrically insulating lateral dielectric layer 550 on at least portions of the side surfaces 513; in some examples the lateral dielectric layer 550 can be contiguous with the back dielectric layer 540. The lateral dielectric layer 550 can circumscribe the entire p-doped layer 502b, the entire active layer 502a, and at least a portion of the n-doped layer 502c; in some of those examples the lateral dielectric layer 550 can circumscribe the entire n-doped layer 502c. The lateral dielectric layer 550 can include one or more materials among: doped or undoped silicon oxide, nitride, or oxynitride; one or more doped or undoped semiconductor oxides, nitrides, or oxynitrides; one or more doped or undoped metal oxides, nitrides, or oxynitrides; one or more optical glasses; or one or more doped or undoped polymers. In some examples the lateral dielectric layer 550 can include only a single layer of a single dielectric material; in other examples the lateral dielectric layer 550 can include multiple layers or multiple materials.

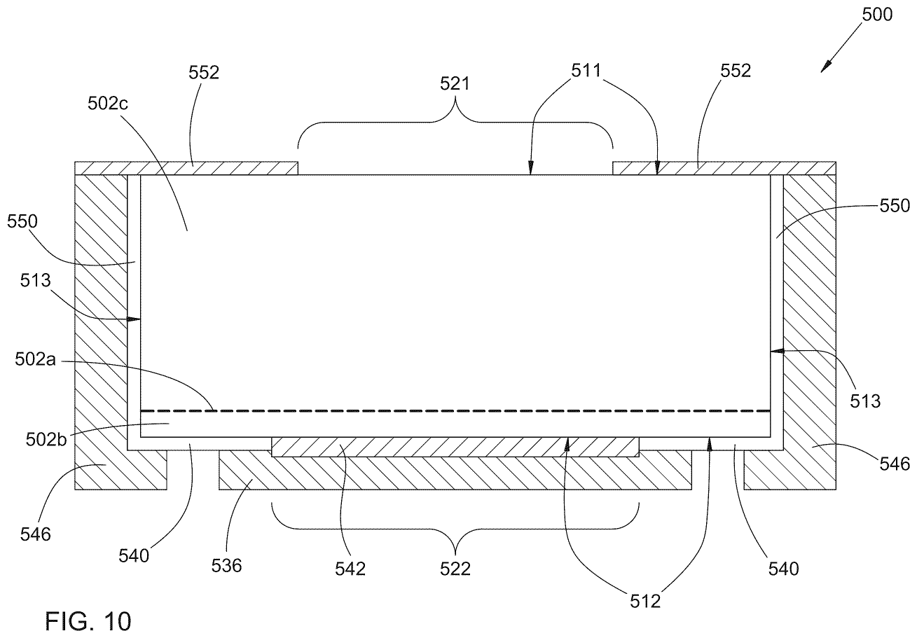

In some examples (e.g., as in any of FIGS. 9B, 10, 11, 12A/12B, 16, 17, or 19), the light-emitting element 500 can include an electrically conductive cathode bonding layer 546 electrically coupled to the cathode electrical contact and electrically isolated from the active and p-doped layers 502a/502b. In some of those examples (e.g., as in any of FIGS. 9B, 12A/12B, 16, 17, or 19), the lateral dielectric layer 550 electrically isolates the active and p-doped layers 502a/502b from the cathode bonding layer 546, and the cathode bonding layer 546 is electrically coupled to the n-doped layer 502c by direct contact with at least a sidewall portion or peripheral portion thereof so as to act as the cathode electrical contact. In some of those examples (e.g., as in any of FIG. 10 or 11), the lateral dielectric layer 550 electrically also isolates the n-doped layer 502c from the cathode bonding layer 546. In some examples the cathode bonding layer 546 can include one or more of aluminum, silver, gold, or other metal or metallic alloy. In some examples at least a portion of the cathode bonding layer 546 can be arranged to act as a lateral reflector at the side surfaces 513.

In some examples the lateral dielectric layer 550 can include a lateral reflector between the side surfaces 513 and the cathode bonding layer 546. In some of those examples the lateral reflector can include a dielectric multilayer reflector or a distributed Bragg reflector, and can include one or more materials among: one or more metals or metal alloys; doped or undoped silicon; one or more doped or undoped III-V, II-VI, or Group IV semiconductors; doped or undoped silicon oxide, nitride, or oxynitride; one or more doped or undoped semiconductor oxides, nitrides, or oxynitrides; one or more doped or undoped metal oxides, nitrides, or oxynitrides; one or more optical glasses; or one or more doped or undoped polymers. If the lateral reflector is electrically conductive, in some examples it can be electrically coupled to the n-doped layer 502c and act as the cathode electrical contact.

In some examples (e.g., as in any of FIG. 12A or 12B) the cathode electrical contact can include a TCO layer 554 in direct contact with at least a portion of the light-exit surface 511. The TCO layer 554 can include one or more of indium tin oxide, indium zinc oxide, one or more other transparent conductive oxides, or combinations or mixtures thereof.

In some examples (e.g., as in any of FIGS. 7-11, 13-16, or 18) the cathode electrical contact can include a metal layer 552 in direct contact with at least a portion of the light-exit surface 511. In some examples the metal layer 552 can act as a reflective or scattering layer on the light-exit surface 511; the metal layer 552 can be formed on peripheral portions of the light-exit surface 511, leaving the central opening 521. In some examples the metal layer 552 can serve as both the cathode electrical contact and the reflective or scattering layer. The metal layer 552 can include one or more of aluminum, silver, gold, or other metal or metallic alloy.

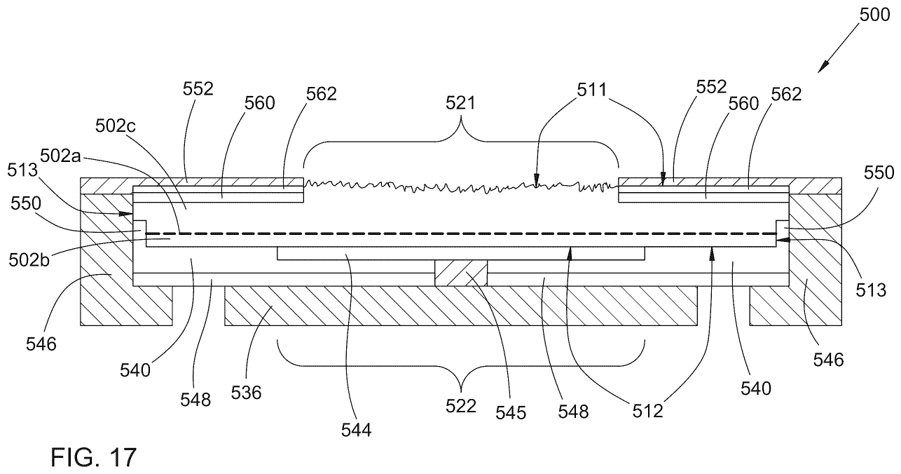

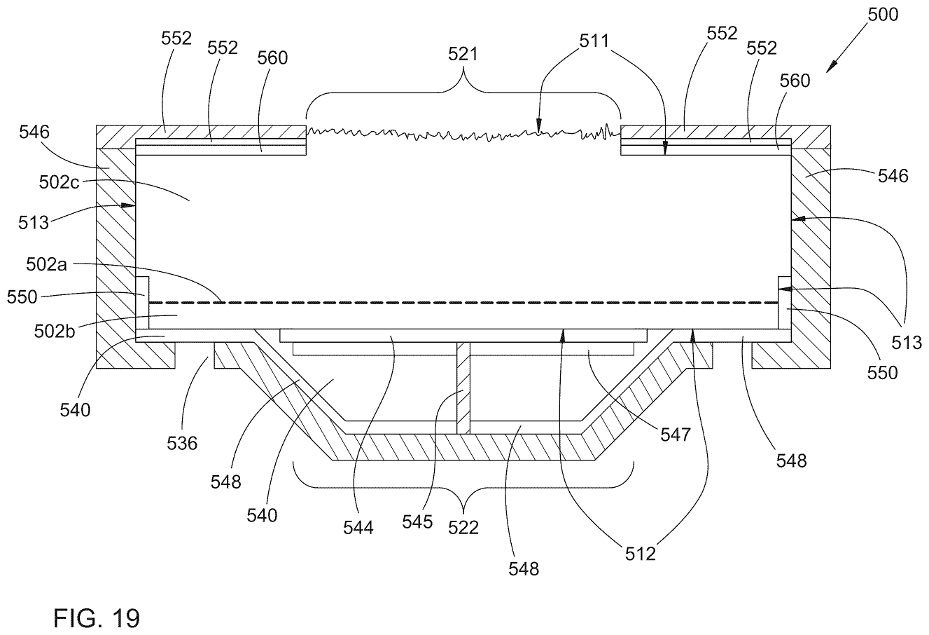

In some examples (e.g., as in any of FIG. 17 or 19) the reflective or scattering layer on the light-exit surface 511 can include one or more front dielectric layers 560. In some examples the front dielectric layer 560 can include only a single layer of a single dielectric material; in other examples the front dielectric layer 560 can include multiple layers or multiple materials. In some examples the front dielectric layer 560 can include one or more materials among: doped or undoped silicon oxide, nitride, or oxynitride; one or more doped or undoped semiconductor oxides, nitrides, or oxynitrides; one or more doped or undoped metal oxides, nitrides, or oxynitrides; one or more optical glasses; or one or more doped or undoped polymers. In some examples the reflective or scattering layer on the light-exit surface 511 can include a dielectric multilayer reflector or a distributed Bragg reflector 562 that can include one or more materials among: one or more metals or metal alloys; doped or undoped silicon; one or more doped or undoped III-V, II-VI, or Group IV semiconductors; doped or undoped silicon oxide, nitride, or oxynitride; one or more doped or undoped semiconductor oxides, nitrides, or oxynitrides; one or more doped or undoped metal oxides, nitrides, or oxynitrides; one or more optical glasses; or one or more doped or undoped polymers. If the front reflective or scattering layer is electrically conductive, it can form at least a portion of the cathode electrical contact; if the front reflective or scattering layer is electrically non-conductive, then the cathode electrical contact can include, e.g., a TCO layer 554 on at least a central area of the light-exit surface 511, direct electrical coupling of the n-doped layer 502c through a side surface 513, or other suitable arrangement.

In some examples (not shown) the light-emitting element 500 can include a front set of multiple nanostructured optical elements characterized by at least one element size relative to the nominal emission vacuum wavelength λ₀ and by at least one element shape (e.g., cylindrical, frusto-conical, frusto-pyramidal and so forth). The nanostructured elements of the front set can be positioned on or within the front dielectric layer 560 or at the light-exit surface 511, and can be arranged as an array of elements characterized by at least one element spacing relative to the nominal emission vacuum wavelength λ₀. The element size, shape, and spacing of the front set can be selected to result in one or both of (1) non-refractive transmissive redirection of at least a portion of light at the nominal emission vacuum wavelength λ₀ transmitted through the light-exit surface 511 or (2) non-specular reflective redirection of at least a portion of light at the nominal emission vacuum wavelength λ₀ incident on the light-exit surface 511 to propagate toward the anode contact surface 512. Examples of such nanostructured layers are disclosed in the various references incorporated above in the discussion of primary and secondary optical elements for the pcLEDs 100 of the array 200.

In some examples the nanostructured elements of the front set can include a multitude of suitably sized and shaped projections, holes, depressions, inclusions, or structures. In some examples the nanostructured elements of the front set can include an array of single or double nano-antennae, a partial photonic bandgap structure, a photonic crystal, or an array of meta-atoms or meta-molecules. In some examples nonzero size or spacing of the nanostructured elements of the front set can be either (i) less than λ₀/n_{N}, less than λ₀/2n_{N}, less than λ₀/4n_{N}, or less than λ₀/10n_{N}, where n_{N} is the refractive index of the n-doped layer, or (ii) less than λ₀/n_{F}, less than λ₀/2n_{F}, less than λ₀/4n_{F}, or less than λ₀/10n_{F}, where n_{F} is the refractive index of the front dielectric layer.

The nanostructured elements of the front set can include one or more materials among: one or more metals or metal alloys; doped or undoped silicon; one or more doped or undoped III-V, II-VI, or Group IV semiconductors; doped or undoped silicon oxide, nitride, or oxynitride; one or more doped or undoped metal oxides, nitrides, or oxynitrides; one or more doped or undoped semiconductor oxides, nitrides, or oxynitrides; one or more optical glasses; or one or more doped or undoped polymers.

In some examples (not shown) the light-emitting element 500 can include an anti-reflection coating on the light-exit surface 511 of the n-doped layer; in some examples the anti-reflection coating is on the light-exit surface 511 within the central opening 521. The anti-reflection coating can be of any suitable type or arrangement for reducing Fresnel reflection of emitted light at the nominal emission vacuum wavelength λ₀ incident on the light-exit surface 511, relative to reflection at a similar surface lacking the anti-reflection coating. Any suitable anti-reflection coating can be employed, e.g., a single quarter-wave layer, a multilayer dielectric stack, a so-called moth's-eye structure, and so forth, and can be suitably arranged based on the refractive indices of the n-doped layer 502c and a medium positioned against the light-exit surface 511.

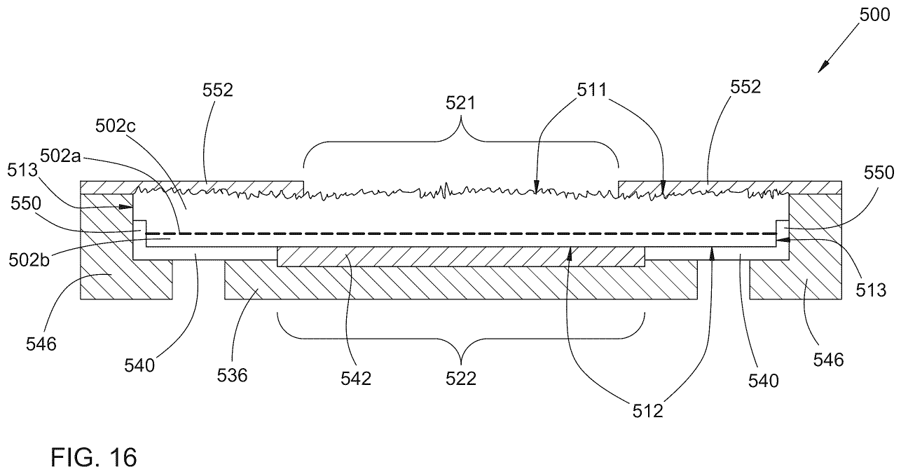

In some examples (e.g., as in any of FIGS. 16-19) the light-exit surface 511 can include roughening, texturing, or patterning. In some examples the roughening, texturing, or patterning can be present on only the area of the central opening 521 of the light-exit surface 511, while in other examples the entire light-exit surface 511 can be roughened, textured, or patterned. Such roughening, texturing, or patterning can be arranged so as to exhibit one or both of (i) increased light extraction efficiency relative to a flat light-exit surface or (ii) non-specular internal reflective redirection, relative to a flat light-exit surface, of light incident on the light-exit surface 511 from within the n-doped layer 502c.

A method for making any of the disclosed light-emitting elements 500 includes: (A) forming the p-and n-doped semiconductor layers 502b/502c with the active layer 502a between them; (B) forming the anode electrical contact electrically coupled to the p-doped semiconductor layer 502b; and (C) forming the cathode electrical contact electrically coupled to the n-doped semiconductor layer 502c. Such a method can include formation of any one or more or all of the structures, features, or arrangements discussed above.

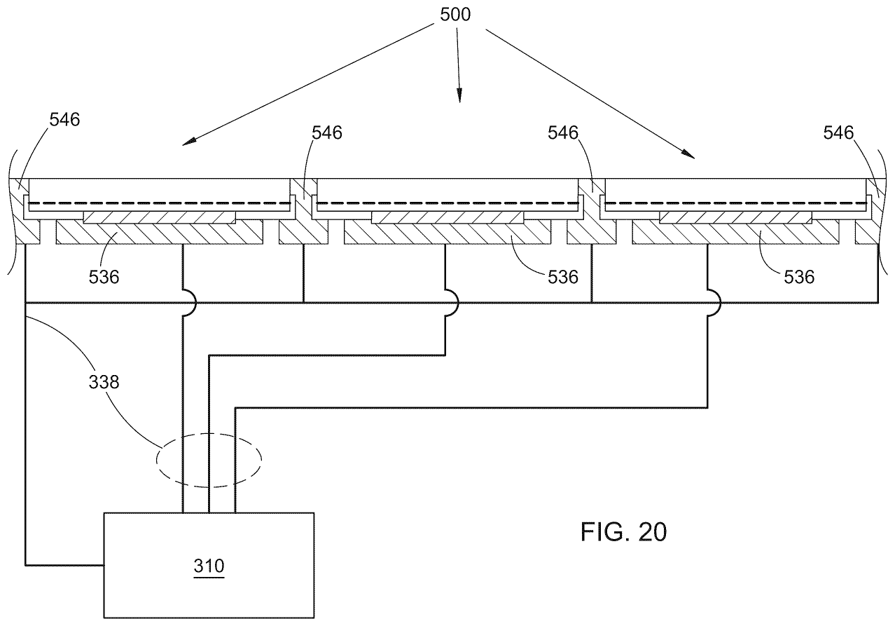

In some examples multiple light-emitting elements 500 can be arranged as a light-emitting array (e.g., as in FIGS. 9A and 9B or FIG. 20; more generally as in any of FIGS. 2A through 6B). The multiple light-emitting elements 500 can be arranged in the array with their corresponding light-exit surfaces 511 in a substantially coplanar arrangement. In some examples the multiple light-emitting elements 500 can comprise discrete, structurally distinct elements assembled together to form the array. In some other examples the multiple light-emitting elements 500 of the array can be integrally formed together on a common substrate. In some integrally formed examples, the corresponding n-doped layers 502c of the LEDs can form a single, continuous n-doped layer spanning the array. In some other integrally formed or assembled examples, the corresponding n-doped layers of the LEDs can be separated from one another with no direct electrical coupling between them.

In some examples of an array, the nonzero spacing of the light-emitting elements 500 can be less than 1.0 mm, less than 0.5 mm, less than 0.3 mm, less than 0.2 mm, less than 0.10 mm, less than 0.08 mm, less than 0.05 mm, less than 0.03 mm, less than 0.02 mm, or less than 0.010 mm. In some examples the nonzero separation between adjacent light-emitting elements 500 of the array can be less than 50 μm, less than 20 μm, less than 10. μm, less than 5 μm, less than 2 μm, less than 1.0 μm, or less than 0.5 μm. In some examples the light-emitting elements 500 of the array can exhibit a contrast ratio for emitted light exiting from adjacent light-emitting elements that is greater than 5:1, greater than 10:1, greater than 20:1, greater than 50:1, greater than 100:1, or greater than 300:1.

In some examples of an array, the array can be arranged so that some or all of the light-emitting elements 500 thereof act as direct emitters, i.e., light emitted from the junction or active layer 502a being the output of the corresponding light-emitting elements 500. In some examples the array can include one or more wavelength-converting structures (e.g., phosphor wavelength converters) on one or more or all of the light-emitting elements 500, so that output from those corresponding elements of the array includes down-converted light emitted by the wavelength-converting structure (with or without residual light emitted by the junction or active layer 502a). In some examples such wavelength-converting structures can all emit at the same one or more wavelengths; in other examples wavelength-converting structures of some light-emitting elements 500 can emit at wavelengths different from those emitted by wavelength-converting structures of some other light-emitting elements 500. In some examples the wavelength-converting structures can be arranged as discrete elements on each light-emitting element 500; in some other examples the wavelength-converting structures can be corresponding areas of a contiguous layer over multiple light-emitting elements 500, or over all of the light-emitting elements 500.

In some examples (e.g., as in FIG. 20) a set of multiple independent electrically conductive traces or interconnects 338 can be connected to the corresponding anode electrical contacts (e.g., through anode bonding layers 536), with each anode electrical contact being connected to a single corresponding one of the traces or interconnects 338 that is different from a corresponding trace or interconnect 338 connected to at least one other anode electrical contact. In some examples each anode electrical contact can be connected to a single corresponding one of the traces or interconnects 338 that is different from a corresponding trace or interconnect connected 338 to all other anode electrical contacts. Another electrical trace or interconnect 338 can be connected to the cathode electrical contacts (e.g., through cathode bonding layers 546). In some examples the one or more electrically conductive traces or interconnects 338 can include one or more metals or metal alloys, e.g., one or more of aluminum, silver, or gold.

In some examples a drive circuit 310 of any suitable type or arrangement (e.g., incorporating any suitable analog circuity, digital circuitry, general or application-specific integrated circuits, microprocessors, or combinations thereof) can be connected by the electrical traces or interconnects 338 to each of the cathode electrical contacts and to each of the anode electrical contacts. In some examples the drive circuit 310 can be structured and connected so as to provide electrical drive current that flows through the array and causes the array to emit light, and that is further structured and connected so that (i) corresponding portions of the electrical drive current flow through one or more corresponding LEDs as corresponding pixel currents, and (ii) each pixel current magnitude differs from the corresponding pixel current magnitude of at least one other of the LEDs of the array. In some examples differing spatial distributions of pixel current magnitudes to the elements 500 of the array can result in corresponding different spatial distributions of light emission intensity across the array.

Design or optimization one or more or all of, inter alia, the semiconductor layers 502a/502b/502c (e.g., refractive indices, thicknesses, doping levels), diode size or shape, separation between the anode electrical contact and the side surfaces 513, the dielectric layer(s) 540/550/560 (e.g., thickness, refractive index, reflector structure, nanostructured elements), reflectors 548 or 562, any nanostructured layer, or other structures or properties, can be performed (by calculation, simulation, or iterative designing/making/testing of prototypes or test devices) based on one or more selected figures-of-merit (FOMs). Device-performance-based FOMs that can be considered can include, e.g.: (i) extraction efficiency; (ii) total radiated emission; (iii) radiated angular distribution of the emitted light; (iv) fraction of radiated emission within a selected cone angle; (v) contrast ratio between adjacent pixel regions for light emission, or (vi) other suitable or desirable FOMs. Instead or in addition, reduction of cost or manufacturing complexity can be employed as an FOM in a design or optimization process.

Optimization for one FOM can result in non-optimal values for one or more other FOMs. Note that a device that is not necessarily fully optimized with respect to any FOM can nevertheless provide acceptable enhancement of one or more FOMs; such partly optimized devices fall within the scope of the present disclosure or appended claims.

A method for using an array incorporating any of the disclosed light-emitting elements 500 includes: (A) selecting a first specified spatial distribution of element current magnitudes; (B) operating the drive circuit to provide the first specified spatial distribution of element current magnitudes to the elements 500 of the array, causing the array to emit light according to a corresponding first spatial distribution of light emission intensity across the array; (C) selecting a second specified spatial distribution of element current magnitudes that differs from the first specified spatial distribution of element current magnitudes; and (D) operating the drive circuit to provide the second specified spatial distribution of element current magnitudes to the elements 500 of the array, causing the array to emit light according to a corresponding second spatial distribution of light emission intensity across the array that differs from the first spatial distribution of light emission intensity.

A method for making an array incorporating any of the disclosed light-emitting elements includes: (A) forming or assembling the multiple light-emitting elements 500 to form the array; (B) forming one or more electrical traces or interconnects 338 connected to the corresponding anode electrical contacts; and (C) connecting the drive circuit 310 (i) to the corresponding anode electrical contacts using corresponding electrical traces or interconnects 338, and (ii) to the corresponding cathode electrical contacts using at least one corresponding trace or interconnect 338.

In addition to the preceding, the following example embodiments fall within the scope of the present disclosure or appended claims:

Example 1. A light-emitting element comprising: (a) a semiconductor light-emitting diode (LED) that includes a p-doped semiconductor layer, an n-doped semiconductor layer, and an active, light-emitting layer between the p-doped and n-doped layers, the LED being arranged for emitting light at a nominal emission vacuum wavelength λ₀ resulting from radiative recombination of charge carriers at the active layer, the LED having (i) a light-exit surface of the n-doped layer opposite the active layer, (ii) an anode contact surface of the p-doped layer opposite the active layer, and (iii) side surfaces that laterally confine the entire p-doped layer, the entire active layer, and at least a portion of the n-doped layer, the active layer extending to the side surfaces; (b) an anode electrical contact electrically coupled to the p-doped layer on only a central area of the anode contact surface, the central area being circumscribed by peripheral portions of the anode contact surface that lack direct electrical coupling to the anode electrical contact; and (c) a cathode electrical contact electrically coupled to the n-doped layer.

Example 2. The light-emitting element of Example 1 further comprising reflective or scattering layers on peripheral portions of the light-exit surface, at least portions of the anode contact surface, or at least portions of the side surfaces, the reflective or scattering layer on the light-exit surface having a central opening therethrough, the reflective or scattering layers forming an optical cavity at least partly enclosing the n- and p-doped semiconductor layers and the active layer.

Example 3. The light-emitting element of Example 1 further comprising a reflective or scattering layer on peripheral portions of the light-exit surface and having a central opening therethrough, at least a portion of the central opening being positioned opposite at least a portion of the central area of the anode contact surface.

Example 4. The light-emitting element of Example 1 further comprising reflective or scattering layers on peripheral portions of the light-exit surface, at least portions of the anode contact surface, or at least portions the side surfaces, the reflective or scattering layer on the light-exit surface having a central opening therethrough, at least a portion of the central opening being positioned opposite at least a portion of the central area of the anode contact surface, the reflective or scattering layers forming an optical cavity at least partly enclosing the n-and p-doped semiconductor layers and the active layer.

Example 5. A light-emitting element comprising: (a) a semiconductor light-emitting diode (LED) that includes a p-doped semiconductor layer, an n-doped semiconductor layer, and an active, light-emitting layer between the p-doped and n-doped layers, the LED being arranged for emitting light at a nominal emission vacuum wavelength λ₀ resulting from radiative recombination of charge carriers at the active layer, the LED having (i) a light-exit surface of the n-doped layer opposite the active layer, (ii) an anode contact surface of the p-doped layer opposite the active layer, and (iii) side surfaces that laterally confine the entire p-doped layer, the entire active layer, and at least a portion of the n-doped layer, the active layer extending to the side surfaces; (b) an anode electrical contact electrically coupled to the p-doped layer on a central area of the anode contact surface leaving peripheral portions of the anode contact surface without direct electrical coupling to the anode electrical contact; (c) a cathode electrical contact electrically coupled to the n-doped layer; and (d) a reflective or scattering layer on peripheral portions of the light-exit surface and having a central opening therethrough, at least a portion of the central opening being positioned opposite at least a portion of the central area of the anode contact surface.

Example 6. The light-emitting element of any one of Examples 3 through 5, the entire central opening being positioned opposite at least a portion of the central area of the anode contact surface.

Example 7. The light-emitting element of any one of Examples 3 through 5, the entire central area of the anode contact surface being positioned opposite at least a portion of the central opening.

Example 8. The light-emitting element of any one of Examples 3 through 7, the central opening being concentrically positioned opposite the central area of the anode contact surface.

Example 9. The light-emitting element of Example 8, the central opening and the central area of the anode contact surface being substantially the same size and shape.

Example 10. A light-emitting element comprising: (a) a semiconductor light-emitting diode (LED) that includes a p-doped semiconductor layer, an n-doped semiconductor layer, and an active, light-emitting layer between the p-doped and n-doped layers, the LED being arranged for emitting light at a nominal emission vacuum wavelength λ₀ resulting from radiative recombination of charge carriers at the active layer, the LED having (i) a light-exit surface of the n-doped layer opposite the active layer, (ii) an anode contact surface of the p-doped layer opposite the active layer, and (iii) side surfaces that laterally confine the entire p-doped layer, the entire active layer, and at least a portion of the n-doped layer, the active layer extending to the side surfaces; (b) an anode electrical contact electrically coupled to the p-doped layer on a central area of the anode contact surface leaving peripheral portions of the anode contact surface without direct electrical coupling to the anode electrical contact; (c) a cathode electrical contact electrically coupled to the n-doped layer; and (d) reflective or scattering layers on peripheral portions of the light-exit surface, at least portions of the anode contact surface, or at least positions of the side surfaces, the reflective or scattering layer on the light-exit surface having a central opening therethrough, the reflective or scattering layers forming an optical cavity at least partly enclosing the n- and p-doped semiconductor layers and the active layer.

Example 11. The light-emitting element of any one of Examples 2 through 10, separation between lateral edges of the central opening and the side surfaces being greater than 1.0 μm, 2 μm, 5 μm, 10. μm, 20 μm, or 50 μm.

Example 12. The light-emitting element of any one of Examples 1 through 11, separation between lateral edges of the anode electrical contact and the side surfaces being larger than a characteristic lateral diffusion distance of charge carriers diffusing along the active layer within a characteristic radiative lifetime of those diffusing charge carriers.

Example 13. The light-emitting element of any one of Examples 1 through 12, separation between lateral edges of the anode electrical contact and the side surfaces being greater than 1.0 μm, 2.0 μm, 5 μm, 10. μm, 20. μm, or 50 μm.

Example 14. The light-emitting element of any one of Examples 1 through 13, the side surfaces laterally confining the entire n-doped layer.

Example 15. The light-emitting element of any one of Examples 1 through 14, the side surfaces being substantially flat and substantially perpendicular to the light-exit surface and the anode contact surface.

Example 16. The light-emitting element of any one of Examples 1 through 14, the side surfaces forming obtuse internal angles with the anode contact surface.

Example 17. The light-emitting element of any one of Examples 1 through 14, the side surfaces forming obtuse internal angles with the light-exit surface.

Example 18. The light-emitting element of any one of Examples 1 through 17 further comprising an electrically insulating back dielectric layer on the peripheral portions of the anode contact surface that lack direct electrical coupling to the anode electrical contact.

Example 19. The light-emitting element of Example 18, the back dielectric layer including one or more materials among: doped or undoped silicon oxide, nitride, or oxynitride; one or more doped or undoped semiconductor oxides, nitrides, or oxynitrides; one or more doped or undoped metal oxides, nitrides, or oxynitrides; one or more optical glasses; or one or more doped or undoped polymers.

Example 20. The light-emitting element of any one of Examples 1 through 19, the anode electrical contact comprising a metal layer in direct contact with the central area of the anode contact surface, the metal layer including one or more of aluminum, silver, gold, or other metal or metallic alloy.

Example 21. The light-emitting element of Example 20, the anode electrical contact being a portion of an electrically conductive anode bonding layer in direct electrical contact with the central area of the anode contact surface.

Example 22. The light-emitting element of any one of Examples 1 through 19, the anode electrical contact comprising a transparent conductive oxide (TCO) layer in direct contact with the central area of the anode contact surface, the TCO layer including one or more of indium tin oxide, indium zinc oxide, one or more other transparent conductive oxides, or combinations or mixtures thereof.

Example 23. The light-emitting element of Example 22, the back dielectric layer covering the TCO layer opposite the anode contact surface, the light-emitting element further comprising at least one circumscribed, localized, electrically conductive via electrically coupled to the TCO layer and passing through the back dielectric layer.

Example 24. The light-emitting element of Example 23 further comprising a back reflector on the back dielectric layer opposite the TCO layer and the anode contact surface.

Example 25. The light-emitting element of Example 24, the back reflector including one or more of a metal layer, a dielectric multilayer reflector, or a distributed Bragg reflector.

Example 26. The light-emitting element of any one of Examples 24 or 25, the back reflector including one or more materials among: one or more metals or metal alloys; doped or undoped silicon; one or more doped or undoped III-V, II-VI, or Group IV semiconductors; doped or undoped silicon oxide, nitride, or oxynitride; one or more doped or undoped semiconductor oxides, nitrides, or oxynitrides; one or more doped or undoped metal oxides, nitrides, or oxynitrides; one or more optical glasses; or one or more doped or undoped polymers.

Example 27. The light-emitting element of any one of Examples 18 through 26, the back dielectric layer including a central portion opposite at least the central area of the anode contact surface that protrudes away from the anode contact surface and that is arranged so as to redirect a portion of light propagating from the active layer through the anode contact surface to propagate back through the anode contact surface toward the light-exit surface.

Example 28. The light-emitting element of Example 27, the protruding central portion of the back dielectric layer having a tapered shape that decreases in transverse extent with increasing distance from the anode contact surface.

Example 29. The light-emitting element of any one of Examples 18 through 28 further comprising a back set of multiple nanostructured optical elements (i) positioned on or within the back dielectric layer or at the anode contact surface, (ii) characterized by at least one element size relative to the nominal emission vacuum wavelength λ₀ and by at least one element shape, and (iii) arranged as an array of elements characterized by at least one element spacing relative to the nominal emission vacuum wavelength λ₀, (iv) the element size, shape, and spacing of the back set resulting in one or more of (1) non-specular reflective redirection of at least a portion of light at the nominal emission vacuum wavelength λ₀ propagating within the dielectric layer to propagate toward the light-exit surface, (2) non-specular reflective or non-refractive transmissive redirection of at least a portion of light at the nominal emission vacuum wavelength λ₀ incident on the anode contact surface to propagate toward the light-exit surface, (3) increased Purcell factor for emission of light by the active layer, or (4) enhanced directionality of light emitted by the active layer.

Example 30. The light-emitting array of Example 29, the nanostructured elements of the back set including a multitude of suitably sized and shaped projections, holes, depressions, inclusions, or structures.

Example 31. The light-emitting array of any one of Examples 29 or 30, the nanostructured elements of the back set including an array of single or double nano-antennae, a partial photonic bandgap structure, a photonic crystal, or an array of meta-atoms or meta-molecules.

Example 32. The light-emitting array of any one of Examples 29 through 31, nonzero size or spacing of the nanostructured elements of the back set being less than λ₀/n_{P}, less than λ₀/2n_{P}, less than λ₀/4n_{P}, or less than λ₀/10n_{P}, n_{P} being the refractive index of the p-doped layer.

Example 33. The light-emitting array of any one of Examples 29 through 32, nonzero spacing between the active layer and the nanostructured elements of the back set being less than λ₀/n_{P}, less than λ₀/2n_{P}, less than λ₀/4n_{P}, or less than λ₀/10n_{P}, n_{P} being the refractive index of the p-doped layer.

Example 34. The light-emitting array of any one of Examples 29 through 33, nonzero size or spacing of the nanostructured elements of the back set being less than λ₀/n_{B}, less than λ₀/2n_{B}, less than λ₀/4n_{B}, or less than λ₀/10n_{B}, n_{B} being the refractive index of the back dielectric layer.

Example 35. The light-emitting array of any one of Examples 29 through 34, the nanostructured elements of the back set including one or more materials among: one or more metals or metal alloys; doped or undoped silicon; one or more doped or undoped III-V, II-VI, or Group IV semiconductors; doped or undoped silicon oxide, nitride, or oxynitride; one or more doped or undoped metal oxides, nitrides, or oxynitrides; one or more doped or undoped semiconductor oxides, nitrides, or oxynitrides; one or more optical glasses; or one or more doped or undoped polymers.

Example 36. The light-emitting element of any one of Examples 1 through 35 further comprising an electrically conductive anode bonding layer electrically coupled to the anode contact surface by the anode electrical contact and electrically isolated from the active and n-doped layers.

Example 37. The light-emitting element of Example 36, the anode bonding layer including one or more of aluminum, silver, gold, or other metal or metallic alloy.

Example 38. The light-emitting element of any one of Examples 36 or 37, the anode electrical contact including a transparent conductive oxide (TCO) layer between the anode bonding layer and the anode contact surface and in direct contact with the central area of the anode contact surface, the TCO layer including one or more of indium tin oxide, indium zinc oxide, one or more other transparent conductive oxides, or combinations or mixtures thereof.

Example 39. The light-emitting element of any one of Examples 18 through 38 further comprising an electrically insulating lateral dielectric layer on at least portions of the side surfaces, the lateral dielectric layer being contiguous with the back dielectric layer and circumscribing the entire p-doped layer, the entire active layer, and at least a portion of the n-doped layer.

Example 40. The light-emitting element of any one of Examples 1 through 38 further comprising an electrically insulating lateral dielectric layer on at least portions of the side surfaces, the lateral dielectric layer circumscribing the entire p-doped layer, the entire active layer, and at least a portion of the n-doped layer.

Example 41. The light-emitting element of any one of Examples 39 or 40, the lateral dielectric layer including one or more materials among: doped or undoped silicon oxide, nitride, or oxynitride; one or more doped or undoped semiconductor oxides, nitrides, or oxynitrides; one or more doped or undoped metal oxides, nitrides, or oxynitrides; one or more optical glasses; or one or more doped or undoped polymers.

Example 42. The light-emitting element of any one of Examples 39 through 41, the lateral dielectric layer circumscribing the entire n-doped layer.

Example 43. The light-emitting element of any one of Examples 39 through 41, further comprising an electrically conductive cathode bonding layer electrically coupled to the cathode electrical contact, the lateral dielectric layer electrically isolating the p-doped and active layers from the cathode bonding layer, the cathode bonding layer being electrically coupled to the n-doped layer by direct contact with at least a sidewall portion or peripheral portion thereof so as to act as the cathode electrical contact.

Example 44. The light-emitting element of any one of Examples 39 through 42, further comprising an electrically conductive cathode bonding layer electrically coupled to the cathode electrical contact, the lateral dielectric layer electrically isolating the p-doped and active layers from the cathode bonding layer.

Example 45. The light-emitting element of any one of Examples 43 or 44, the cathode bonding layer including one or more of aluminum, silver, gold, or other metal or metallic alloy.

Example 46. The light-emitting element of any one of Examples 43 through 45, at least a portion of the cathode bonding layer being arranged to act as a lateral reflector at the sidewalls.

Example 47. The light-emitting element of any one of Examples 39 through 46, the lateral dielectric layer comprising a single layer of a single dielectric material.

Example 48. The light-emitting element of any one of Examples 39 through 46, the lateral dielectric layer including a lateral reflector between the side surfaces and the bonding layer.

Example 49. The light-emitting element of Example 48, the lateral reflector including a dielectric multilayer reflector or a distributed Bragg reflector.

Example 50. The light-emitting element of any one of Examples 48 or 49, the lateral reflector including one or more materials among: one or more metals or metal alloys; doped or undoped silicon; one or more doped or undoped III-V, II-VI, or Group IV semiconductors; doped or undoped silicon oxide, nitride, or oxynitride; one or more doped or undoped semiconductor oxides, nitrides, or oxynitrides; one or more doped or undoped metal oxides, nitrides, or oxynitrides; one or more optical glasses; or one or more doped or undoped polymers.

Example 51. The light-emitting element of any one of Examples 1 through 50 further comprising an electrically conductive cathode bonding layer electrically coupled to the cathode electrical contact and electrically isolated from the p-doped and active layers.

Example 52. The light-emitting element of Example 51, the cathode bonding layer including one or more of aluminum, silver, gold, or other metal or metallic alloy.

Example 53. The light-emitting element of any one of Examples 1 through 52, the cathode electrical contact including a TCO layer in direct contact with at least a portion of the light-exit surface, the TCO layer including one or more of indium tin oxide, indium zinc oxide, one or more other transparent conductive oxides, or combinations or mixtures thereof.

Example 54. The light-emitting element of any one of Examples 1 through 52, the cathode electrical contact including a metal layer in direct contact with at least a portion of the light-exit surface, the metal layer including one or more of aluminum, silver, gold, or other metal or metallic alloy.

Example 55. The light-emitting device of any one of Examples 2 through 54, the reflective or scattering layer on the light-exit surface including a metal layer, the metal layer including one or more of aluminum, silver, gold, or other metal or metallic alloy.

Example 56. The light-emitting device of Example 55, the metal layer forming at least a portion of the cathode electrical contact.

Example 57. The light-emitting device of any one of Examples 2 through 56, the reflective or scattering layer on the light-exit surface including one or more front dielectric layers.

Example 58. The light-emitting device of Example 57, the one or more front dielectric layers including one or more materials among: doped or undoped silicon oxide, nitride, or oxynitride; one or more doped or undoped semiconductor oxides, nitrides, or oxynitrides; one or more doped or undoped metal oxides, nitrides, or oxynitrides; one or more optical glasses; or one or more doped or undoped polymers.

Example 59. The light-emitting element of any one of Examples 57 or 58, the front dielectric layer comprising a single layer of a single dielectric material.

Example 60. The light-emitting element of any one of Examples 57 or 58, the reflective or scattering layer on the light-exit surface including a dielectric multilayer reflector or a distributed Bragg reflector.

Example 61. The light-emitting element of Example 60, the reflective or scattering layer on the light-exit surface including one or more materials among: one or more metals or metal alloys; doped or undoped silicon; one or more doped or undoped III-V, II-VI, or Group IV semiconductors; doped or undoped silicon oxide, nitride, or oxynitride; one or more doped or undoped semiconductor oxides, nitrides, or oxynitrides; one or more doped or undoped metal oxides, nitrides, or oxynitrides; one or more optical glasses; or one or more doped or undoped polymers.

Example 62. The light-emitting element of any one of Examples 1 through 61 further comprising a front set of multiple nanostructured optical elements (i) positioned on or within the front dielectric layer or at the light-exit surface, (ii) characterized by at least one element size relative to the nominal emission vacuum wavelength λ₀ and by at least one element shape, and (iii) arranged as an array of elements characterized by at least one element spacing relative to the nominal emission vacuum wavelength λ₀, (iv) the element size, shape, and spacing of the front set resulting in one or both of (1) non-refractive transmissive redirection of at least a portion of light at the nominal emission vacuum wavelength λ₀ transmitted through the light-exit surface or (2) non-specular reflective redirection of at least a portion of light at the nominal emission vacuum wavelength λ₀ incident on the light-exit surface to propagate toward the anode contact surface.

Example 63. The light-emitting array of Example 62, the nanostructured elements of the front set including a multitude of suitably sized and shaped projections, holes, depressions, inclusions, or structures.

Example 64. The light-emitting array of any one of Examples 62 or 63, the nanostructured elements of the front set including an array of single or double nano-antennae, a partial photonic bandgap structure, a photonic crystal, or an array of meta-atoms or meta-molecules.

Example 65. The light-emitting array of any one of Examples 62 through 64, nonzero size or spacing of the nanostructured elements of the front set being either (i) less than λ₀/n_{N}, less than λ₀/2n_{N}, less than λ₀/4n_{N}, or less than λ₀/10n_{N}, n_{N} being the refractive index of the n-doped layer, or (ii) less than λ₀/n_{F}, less than λ₀/2n_{F}, less than λ₀/4n_{F}, or less than λ₀/10n_{F}, n_{F} being the refractive index of the front dielectric layer.

Example 66. The light-emitting array of any one of Examples 62 through 65, the nanostructured elements of the front set including one or more materials among: one or more metals or metal alloys; doped or undoped silicon; one or more doped or undoped III-V, II-VI, or Group IV semiconductors; doped or undoped silicon oxide, nitride, or oxynitride; one or more doped or undoped metal oxides, nitrides, or oxynitrides; one or more doped or undoped semiconductor oxides, nitrides, or oxynitrides; one or more optical glasses; or one or more doped or undoped polymers.

Example 67. The light-emitting element of any one of Examples 1 through 66, further comprising an anti-reflection coating on at least a portion of the light-exit surface of the n-doped layer, arranged so as to reduce reflection of emitted light at the nominal emission vacuum wavelength λ₀ incident on that surface, relative to reflection at a similar surface lacking the anti-reflection coating.

Example 68. The light-emitting element of any one of Examples 2 through 66, further comprising an anti-reflection coating on the exit surface of the n-doped layer within the central opening, arranged so as to reduce reflection of emitted light at the nominal emission vacuum wavelength λ₀ incident on that surface, relative to reflection at a similar surface lacking the anti-reflection coating.

Example 69. The light-emitting element of any one of Examples 1 through 66, the light-exit surface including roughening, texturing, or patterning arranged so as to exhibit one or both of (i) increased light extraction efficiency relative to a flat light-exit surface or (ii) non-specular internal reflective redirection, relative to a flat light-exit surface, of light incident on the light-exit surface from within the n-doped layer.

Example 70. The light-emitting element of any one of Examples 2 through 66, the light-exit surface including roughening, texturing, or patterning arranged so as to exhibit one or both of (i) increased light extraction efficiency through the central opening relative to a flat light-exit surface or (ii) non-specular internal reflective redirection, relative to a flat light-exit surface, of light incident on the light-exit surface from within the n-doped layer.

Example 71. The light-emitting element of any one of Examples 1 through 70, the LED including one or more doped or undoped III-V, II-VI, or Group IV semiconductor materials or alloys or mixtures thereof.

Example 72. The light-emitting array of any one of Examples 1 through 71, the nominal emission vacuum wavelength λ₀ being greater than 0.20 μm, greater than 0.4 μm, greater than 0.8 μm, less than 10. μm, less than 2.5 μm, or less than 1.0 μm.

Example 73. The light-emitting element of any one of Examples 1 through 72, the active layer including one or more p-n junctions, one or more quantum wells, one or more multi-quantum wells, or one or more quantum dots.

Example 74. The light-emitting element of any one of Examples 1 through 73, total nonzero thickness of the layers of the LED being less than 20 μm, less than 10. μm, less than 5 μm, less than 3 μm, less than 2 μm, less than 1.5 μm, or less than 1.0μm.

Example 75. The light-emitting element of any one of Examples 1 through 74, nonzero thickness of the p-doped layer being less than 2 μm, less than 1.0 μm, less than 0.8 μm, less than 0.5 μm, less than 0.3 μm, less than 0.2 μm, or less than 0.10 μm.

Example 76. The light-emitting element of any one of Examples 1 through 75, the layers of the LED supporting at most 15, 10, 8, 5, or 3 laterally propagating optical modes.

Example 77. The light-emitting element of any one of Examples 1 through 76, nonzero thickness of the p-doped layer being selected so as to result in an angular distribution of emitted light within the LED that approximates a specified angular distribution.

Example 78. A method for making the light-emitting element of any one of Examples 1 through 77, the method comprising: (A) forming the p-and n-doped semiconductor layers with the active layer between them; (B) forming the anode electrical contact electrically coupled to the p-doped semiconductor layer; and (C) forming the cathode electrical contact electrically coupled to the n-doped semiconductor layer.

Example 79. A light-emitting array comprising multiple light-emitting elements of any one of Examples 1 through 77 arranged with corresponding light-exit surfaces thereof in a substantially coplanar arrangement.

Example 80. The light-emitting array of Example 79, the corresponding n-doped layers of the LEDs being separated from one another with no direct electrical coupling between corresponding n-doped layers thereof.

Example 81. The light-emitting array of Example 79, the multiple light-emitting elements comprising discrete, structurally distinct elements assembled together to form the array.

Example 82. The light-emitting array of any one of Examples 79 or 80, the multiple light-emitting elements of the array being integrally formed together on a common substrate.

Example 83. The light-emitting array of Example 82, the corresponding n-doped layers of the LEDs forming a single, continuous n-doped layer spanning the array.

Example 84. The light-emitting array of any one of Examples 79 through 83, nonzero spacing of the light-emitting elements of the array being less than 1.0 mm, less than 0.5 mm, less than 0.3 mm, less than 0.2 mm, less than 0.10 mm, less than 0.08 mm, less than 0.05 mm, less than 0.03 mm, less than 0.02 mm, or less than 0.010 mm.

Example 85. The light-emitting array of any one of Examples 79 through 84, nonzero separation between adjacent light-emitting elements of the array being less than 50 μm, less than 20 μm, less than 10. μm, less than 5.0 μm, less than 2 μm, less than 1.0 μm, or less than 0.5 μm.

Example 86. The light-emitting array of any one of Examples 79 through 85, the light-emitting elements of the array exhibiting a contrast ratio for emitted light exiting from adjacent light-emitting elements that is greater than 5:1, greater than 10:1, greater than 20:1, greater than 50:1, greater than 100:1, or greater than 300:1.

Example 87. The light-emitting array of any one of Examples 79 through 86, further comprising a set of multiple independent electrically conductive traces or interconnects connected to the corresponding anode electrical contacts, each anode electrical contact being connected to a single corresponding one of the traces or interconnects that is different from a corresponding trace or interconnect connected to at least one other anode electrical contact.

Example 88. The light-emitting element of Example 87, the one or more electrically conductive traces or interconnects including one or more of aluminum, silver, gold, or one or more other metals or metal alloys.

Example 89. The light-emitting array of any one of Examples 87 or 88, each anode electrical contact being connected to a single corresponding one of the traces or interconnects that is different from corresponding traces or interconnects connected to all other anode electrical contacts.

Example 90. The light-emitting array of any one of Examples 87 through 89, further comprising a drive circuit (i) connected to each of the cathode electrical contacts, and (ii) connected to each of the anode electrical contacts by the electrical traces or interconnects, the drive circuit being structured and connected so as to provide electrical drive current that flows through the array and causes the array to emit light, and that is further structured and connected so that (i) corresponding portions of the electrical drive current flow through one or more corresponding LEDs as corresponding element currents, and (ii) each element current magnitude differs from the corresponding element current magnitude of at least one other of the LEDs of the array.

Example 91. A method for using the light-emitting array of Example 90, the method comprising: (A) selecting a first specified spatial distribution of element current magnitudes; (B) operating the drive circuit to provide the first specified spatial distribution of element current magnitudes to the LEDs of the array, causing the array to emit light according to a corresponding first spatial distribution of light emission intensity across the array; (C) selecting a second specified spatial distribution of element current magnitudes that differs from the first specified spatial distribution of element current magnitudes; and (D) operating the drive circuit to provide the second specified spatial distribution of element current magnitudes to the LEDs of the array, causing the array to emit light according to a corresponding second spatial distribution of light emission intensity across the array that differs from the first spatial distribution of light emission intensity.

Example 92. A method for making the light-emitting array of Example 90, the method comprising: (A) forming or assembling the multiple light-emitting elements to form the array; (B) forming one or more electrical traces or interconnects connected to the corresponding anode electrical contacts; and (C) connecting the drive circuit (i) to the corresponding anode electrical contacts using the electrical traces or interconnects, and (ii) to the corresponding cathode electrical contacts.

This disclosure is illustrative and not limiting. Further modifications will be apparent to one skilled in the art in light of the present disclosure and are intended to fall within the scope of the present disclosure or appended claims. It is intended that equivalents of the disclosed example embodiments and methods, or modifications thereof, shall fall within the scope of the present disclosure or appended claims.

In the foregoing Detailed Description, various features may be grouped together in several example embodiments for the purpose of streamlining the disclosure. This method of disclosure is not to be interpreted as reflecting an intention that any claimed embodiment requires more features than are expressly recited in the corresponding claim. Rather, as the appended claims reflect, inventive subject matter may lie in less than all features of a single disclosed example embodiment. Therefore, the present disclosure shall be construed as implicitly disclosing any embodiment having any suitable subset of one or more features—which features are shown, described, or claimed in the present application—including those subsets that may not be explicitly disclosed herein. A “suitable” subset of features includes only features that are neither incompatible nor mutually exclusive with respect to any other feature of that subset. Accordingly, the appended claims are hereby incorporated in their entirety into the Detailed Description, with each claim standing on its own as a separate disclosed embodiment. In addition, each of the appended dependent claims shall be interpreted, only for purposes of disclosure by said incorporation of the claims into the Detailed Description, as if written in multiple dependent form and dependent upon all preceding claims with which it is not inconsistent. It should be further noted that the cumulative scope of the appended claims can, but does not necessarily, encompass the whole of the subject matter disclosed in the present application.

The following interpretations shall apply for purposes of the present disclosure and appended claims. The words “comprising,” “including,” “having,” and variants thereof, wherever they appear, shall be construed as open ended terminology, with the same meaning as if a phrase such as “at least” were appended after each instance thereof, unless explicitly stated otherwise. The article “a” shall be interpreted as “one or more” unless “only one,” “a single,” or other similar limitation is stated explicitly or is implicit in the particular context; similarly, the article “the” shall be interpreted as “one or more of the” unless “only one of the,” “a single one of the,” or other similar limitation is stated explicitly or is implicit in the particular context. The conjunction “or” is to be construed inclusively unless: (i) it is explicitly stated otherwise, e.g., by use of “either... or,” “only one of,” or similar language; or (ii) two or more of the listed alternatives are understood or disclosed (implicitly or explicitly) to be incompatible or mutually exclusive within the particular context. In that latter case, “or” would be understood to encompass only those combinations involving non-mutually-exclusive alternatives. In one example, each of “a dog or a cat,” “one or more of a dog or a cat,” and “one or more dogs or cats” would be interpreted as one or more dogs without any cats, or one or more cats without any dogs, or one or more of each. In another example, each of “a dog, a cat, or a mouse,” “one or more of a dog, a cat, or a mouse,” and “one or more dogs, cats, or mice” would be interpreted as (i) one or more dogs without any cats or mice, (ii) one or more cats without and dogs or mice, (iii) one or more mice without any dogs or cats, (iv) one or more dogs and one or more cats without any mice, (v) one or more dogs and one or more mice without any cats, (vi) one or more cats and one or more mice without any dogs, or (vii) one or more dogs, one or more cats, and one or more mice. In another example, each of “two or more of a dog, a cat, or a mouse” or “two or more dogs, cats, or mice” would be interpreted as (i) one or more dogs and one or more cats without any mice, (ii) one or more dogs and one or more mice without any cats, (iii) one or more cats and one or more mice without and dogs, or (iv) one or more dogs, one or more cats, and one or more mice; “three or more,” “four or more,” and so on would be analogously interpreted.

For purposes of the present disclosure or appended claims, when a numerical quantity is recited (with or without terms such as “about,” “about equal to,” “substantially equal to,” “greater than about,” “less than about,” and so forth), standard conventions pertaining to measurement precision, rounding error, and significant digits shall apply, unless a differing interpretation is explicitly set forth. For null quantities described by phrases such as “substantially prevented,” “substantially absent,” “substantially eliminated,” “about equal to zero,” “negligible,” and so forth, each such phrase shall denote the case wherein the quantity in question has been reduced or diminished to such an extent that, for practical purposes in the context of the intended operation or use of the disclosed or claimed apparatus or method, the overall behavior or performance of the apparatus or method does not differ from that which would have occurred had the null quantity in fact been completely removed, exactly equal to zero, or otherwise exactly nulled.

For purposes of the present disclosure and appended claims, any labelling of elements, steps, limitations, or other portions of an embodiment, example, or claim (e.g., first, second, third, etc., (a), (b), (c), etc., or (i), (ii), (iii), etc.) is only for purposes of clarity, and shall not be construed as implying any sort of ordering or precedence of the portions so labelled. If any such ordering or precedence is intended, it will be explicitly recited in the embodiment, example, or claim or, in some instances, it will be implicit or inherent based on the specific content of the embodiment, example, or claim. In the appended claims, if the provisions of 35 USC § 112(f) are desired to be invoked in an apparatus claim, then the word “means” will appear in that apparatus claim. If those provisions are desired to be invoked in a method claim, the words “a step for” will appear in that method claim. Conversely, if the words “means” or “a step for” do not appear in a claim, then the provisions of 35 USC § 112(f) are not intended to be invoked for that claim.

If any one or more disclosures are incorporated herein by reference and such incorporated disclosures conflict in part or whole with, or differ in scope from, the present disclosure, then to the extent of conflict, broader disclosure, or broader definition of terms, the present disclosure controls. If such incorporated disclosures conflict in part or whole with one another, then to the extent of conflict, the later-dated disclosure controls.

The Abstract is provided as required as an aid to those searching for specific subject matter within the patent literature. However, the Abstract is not intended to imply that any elements, features, or limitations recited therein are necessarily encompassed by any particular claim. The scope of subject matter encompassed by each claim shall be determined by the recitation of only that claim.

What is claimed is:

1. A light-emitting element comprising:
a semiconductor light-emitting diode (LED) that includes a p-doped semiconductor layer, an n-doped semiconductor layer, and an active, light-emitting layer between the p-doped and n-doped layers, the LED being arranged for emitting light at a nominal emission vacuum wavelength λ₀ resulting from radiative recombination of charge carriers at the active layer, the LED having (i) a light-exit surface of the n-doped layer opposite the active layer, (ii) an anode contact surface of the p-doped layer opposite the active layer, and (iii) side surfaces that laterally confine the entire p-doped layer, the entire active layer, and at least a portion of the n-doped layer, the active layer extending to the side surfaces;
an anode electrical contact electrically coupled to the p-doped layer on a central area of the anode contact surface leaving peripheral portions of the anode contact surface without direct electrical coupling to the anode electrical contact;
a cathode electrical contact electrically coupled to the n-doped layer;
a reflective or scattering layer on peripheral portions of the light-exit surface and having a central opening therethrough, at least a portion of the central opening being positioned opposite at least a portion of the central area of the anode contact surface; and
one or both of (i) a back set of multiple nanostructured optical elements positioned at the anode contact surface or on or within an electrically insulating back dielectric layer on the peripheral portions of the anode contact surface that lack direct electrical coupling to the anode electrical contact, or (ii) a front set of multiple nanostructured optical elements positioned at the light-exit surface, on or within an electrically insulating front dielectric layer on the light-exit surface, or on or within the reflective or scattering layer.

2. The light-emitting element of claim 1, the entire central opening being positioned opposite at least a portion of the central area of the anode contact surface, or the entire central area of the anode contact surface being positioned opposite at least a portion of the central opening.

3. The light-emitting element of claim 1, the central opening being concentrically positioned opposite the central area of the anode contact surface.

4. The light-emitting element of claim 3, the central opening and the central area of the anode contact surface being substantially the same size and shape.

5. The light-emitting element of claim 1, the anode electrical contact comprising a metal layer in direct contact with the central area of the anode contact surface, the metal layer including one or more of aluminum, silver, gold, or other metal or metallic alloy.

6. The light-emitting element of claim 1 further comprising an electrically insulating back dielectric layer on the peripheral portions of the anode contact surface that lack direct electrical coupling to the anode electrical contact.

7. The light-emitting element of claim 6, the anode electrical contact comprising a transparent conductive oxide (TCO) layer in direct contact with the central area of the anode contact surface, the TCO layer including one or more of indium tin oxide, indium zinc oxide, one or more other transparent conductive oxides, or combinations or mixtures thereof, the back dielectric layer covering the TCO layer opposite the anode contact surface, the light-emitting element further comprising at least one circumscribed, localized, electrically conductive via electrically coupled to the TCO layer and passing through the back dielectric layer.

8. The light-emitting element of claim 7 further comprising a back reflector on the back dielectric layer opposite the TCO layer and the anode contact surface, the back reflector including one or more of a metal layer, a dielectric multilayer reflector, or a distributed Bragg reflector.

9. The light-emitting element of claim 7, the back dielectric layer including a central portion opposite at least the central area of the anode contact surface that protrudes away from the anode contact surface and that is arranged so as to redirect a portion of light propagating from the active layer through the anode contact surface to propagate back through the anode contact surface toward the light-exit surface, the protruding central portion of the back dielectric layer having a tapered shape that decreases in transverse extent with increasing distance from the anode contact surface.

10. The light-emitting element of claim 1 wherein:
(A) the device includes the back set of multiple nanostructured optical elements that are (i) characterized by at least one element size relative to the nominal emission vacuum wavelength λ₀ and by at least one element shape and (ii) arranged as an array of elements characterized by at least one element spacing relative to the nominal emission vacuum wavelength λ₀, (iii) the element size, shape, and spacing of the back set resulting in one or more of (1) non-specular reflective redirection of at least a portion of light at the nominal emission vacuum wavelength λ₀ propagating within the back dielectric layer to propagate toward the light-exit surface, (2) non-specular reflective or non-refractive transmissive redirection of at least a portion of light at the nominal emission vacuum wavelength λ₀ incident on the anode contact surface to propagate toward the light-exit surface, (3) increased Purcell factor for emission of light by the active layer, or (4) enhanced directionality of light emitted by the active layer; or
(B) the device includes the front set of multiple nanostructured optical elements that are (i) characterized by at least one element size relative to the nominal emission vacuum wavelength λ₀ and by at least one element shape and (ii) arranged as an array of elements characterized by at least one element spacing relative to the nominal emission vacuum wavelength λ₀, (iii) the element size, shape, and spacing of the front set resulting in one or more of (1) non-specular reflective redirection of at least a portion of light at the nominal emission vacuum wavelength λ₀ propagating within the front dielectric layer, (2) non-specular reflective or non-refractive transmissive redirection of at least a portion of light at the nominal emission vacuum wavelength λ₀ incident on the light-exit surface, (3) increased Purcell factor for emission of light by the active layer, or (4) enhanced directionality of light emitted by the active layer.

11. The light-emitting element of claim 1 further comprising an electrically conductive anode bonding layer electrically coupled to the anode contact surface by the anode electrical contact and electrically isolated from the active and n-doped layers.

12. The light-emitting element of claim 1 further comprising an electrically insulating lateral dielectric layer on at least portions of the side surfaces, the lateral dielectric layer circumscribing the entire p-doped layer, the entire active layer, and at least a portion of the n-doped layer.

13. The light-emitting element of claim 12 further comprising an electrically conductive cathode bonding layer electrically coupled to the cathode electrical contact, the lateral dielectric layer electrically isolating the p-doped and active layers from the cathode bonding layer.

14. The light-emitting element of claim 13, the lateral dielectric layer including a lateral reflector between the side surfaces and the bonding layer, the lateral reflector including a dielectric multilayer reflector or a distributed Bragg reflector.

15. The light-emitting element of claim 1, the cathode electrical contact including a TCO layer in direct contact with at least a portion of the light-exit surface, the TCO layer including one or more of indium tin oxide, indium zinc oxide, one or more other transparent conductive oxides, or combinations or mixtures thereof.

16. The light-emitting element of claim 1, the cathode electrical contact including a metal layer in direct contact with at least a portion of the light-exit surface, the metal layer including one or more of aluminum, silver, gold, or other metal or metallic alloy, the metal layer acting as a reflector.

17. The light-emitting device of claim 1, the reflective or scattering layer on the light-exit surface including one or more front dielectric layers, a dielectric multilayer reflector, or a distributed Bragg reflector.

18. The light-emitting element of claim 1, the light-exit surface including roughening, texturing, or patterning arranged so as to exhibit one or both of (i) increased light extraction efficiency relative to a flat light-exit surface or (ii) non-specular internal reflective redirection, relative to a flat light-exit surface, of light incident on the light-exit surface from within the n-doped layer.

19. A light-emitting array comprising multiple light-emitting elements of claim 1 arranged with corresponding light-exit surfaces thereof in a substantially coplanar arrangement.

20. The light-emitting array of claim 19, nonzero spacing of the light-emitting elements of the array being less than 0.2 mm, and nonzero separation between adjacent light-emitting elements of the array being less than 0.05 mm.
